(19) United States
(12) Patent Application Publication
(10) Pub. No.: US 2025/0143025 A1
(43) Pub. Date: May 1, 2025

(54) DISPLAY DEVICE AND METHOD FOR MANUFACTURING THE SAME

(71) Applicant: Samsung Display Co., LTD., Yongin-si (KR)

(72) Inventors: Ki Seong SEO, Yongin-si (KR); Jong Moo HUH, Yongin-si (KR); Jae Phil LEE, Yongin-si (KR); Ju Yon LEE, Yongin-si (KR); Min Sik JUNG, Yongin-si (KR)

(21) Appl. No.: 18/740,310

(22) Filed: Jun. 11, 2024

(30) Foreign Application Priority Data
Oct. 31, 2023 (KR) 10-2023-0147339

(51) Int. Cl. H01L 33/38; H01L 25/16; H01L 33/62

(52) U.S. Cl. CPC H10H 20/831; H01L 25/167; H10H 20/857; H10H 20/032; H10H 20/0364

(57) ABSTRACT

Provided are a display device and a method for manufacturing the same. According to one or more embodiments of the present disclosure, the display device includes a substrate, a pixel electrode above the substrate, an organic layer above the pixel electrode, a light-emitting element above the organic layer, and including a contact electrode in contact with the organic layer, and a connection electrode connected to the pixel electrode and to the contact electrode, on a side surface of the organic layer, and on a side surface of the contact electrode.

### CROSS-REFERENCE TO RELATED APPLICATION

This application claims priority to, and the benefit of, Korean Patent Application No. 10-2023-0147339 filed on Oct. 31, 2023, in the Korean Intellectual Property Office, the entire disclosure of which is incorporated by reference herein.

### BACKGROUND

### 1. Field

One or more embodiments of the present disclosure relate to a display device and a method for manufacturing the same.

### 2. Description of the Related Art

With the advance of information-oriented society, more and more demands are placed on display devices for displaying images in various ways. The display device may be a flat panel display device, such as a liquid crystal display, a field emission display and a light-emitting display. The light-emitting display may include an organic light-emitting display including an organic light-emitting diode element as a light-emitting element, and an ultra-small light-emitting display including an ultra-small light-emitting diode element (hereinafter, referred to as a micro light-emitting diode element) as a light-emitting element.

When an ultra-small light-emitting display is manufactured, a micro light-emitting element may be suitably bonded to a pixel electrode of a display panel, but the micro light-emitting element may not be electrically connected to the pixel electrode due to tilting or falling. Due to bonding failure between the micro light-emitting element and the pixel electrode, the micro light-emitting element may not emit light.

### SUMMARY

Aspects of embodiments of the present disclosure provide a display device capable of reducing or preventing the micro light-emitting element from becoming unable to be electrically connected to the pixel electrode due to tilting or falling, and a method for manufacturing the same.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is provided a display device including a substrate, a pixel electrode above the substrate, an organic layer above the pixel electrode, a light-emitting element above the organic layer, and including a contact electrode in contact with the organic layer, and a connection electrode connected to the pixel electrode and to the contact electrode, on a side surface of the organic layer, and on a side surface of the contact electrode.

The light-emitting element may include a first semiconductor layer above the contact electrode, an active layer above the first semiconductor layer, a second semiconductor layer above the active layer, and a passivation layer on a side surface of the first semiconductor layer, on a side surface of the active layer, and on a side surface of the second semiconductor layer, wherein the connection electrode is on the passivation layer.

The display device may further include a first organic layer covering the connection electrode, wherein a portion of the passivation layer is exposed without being covered by the first organic layer.

The display device may further include a second organic layer above the first organic layer, and covering the portion of the passivation layer, and a common electrode above top surfaces of the second organic layer and the second semiconductor layer.

The display device may further include a bank covering an edge of the pixel electrode and an edge of the connection electrode, a first light-blocking layer above the common electrode, and overlapping the bank in a thickness direction of the substrate, a second light-blocking layer above the first light-blocking layer, a light conversion layer or light-transmitting layer above the common electrode, overlapping the light-emitting element in the thickness direction of the substrate, and in a region defined by the first light-blocking layer and the second light-blocking layer, and a color filter above the light conversion layer or the light-transmitting layer.

The contact electrode may cover at least a portion of the passivation layer.

The contact electrode may be on a bottom surface of the first semiconductor layer of the light-emitting element, and on a bottom surface of the passivation layer.

A length of the contact electrode in a first direction may be less than a length of a bottom surface of the first semiconductor layer in the first direction.

The connection electrode may be on a bottom surface of the first semiconductor layer.

The connection electrode may be on a bottom surface of the passivation layer.

A side surface of the contact electrode may protrude more than a side surface of the organic layer.

The connection electrode may be on a portion of a bottom surface of the contact electrode.

A side surface of the organic layer may protrude more than a side surface of the contact electrode.

The connection electrode may be above a top surface of the organic layer exposed without being covered by the contact electrode.

A thickness of the organic layer may be greater than a thickness of the pixel electrode.

A thickness of the organic layer may be greater than a thickness of the contact electrode.

A portion of a top surface of the pixel electrode may be exposed without being covered by the organic layer, wherein the connection electrode is above a portion of the top surface of the pixel electrode.

According to one or more embodiments of the present disclosure, there is provided a display device including a substrate, a pixel electrode and a common electrode above the substrate, and spaced apart from each other, an organic layer above the pixel electrode and the common electrode, a light-emitting element above the organic layer, and including a first contact electrode and a second contact electrode in contact with the organic layer, a first connection electrode connected to the pixel electrode and the first contact electrode, on a portion of a side surface of the organic layer, and on a side surface of the first contact electrode, and a second connection electrode connected to the common electrode and the second contact electrode, on another portion of the side surface of the organic layer, and on a side surface of the second contact electrode.

A portion of a top surface of the pixel electrode may be exposed without being covered by the organic layer, wherein the first connection electrode is above the portion of the top surface of the pixel electrode.

The light-emitting element may include a first portion above the first contact electrode, and including a first semiconductor layer, an active layer, and a second semiconductor layer, a second portion above the second contact electrode, including the second semiconductor layer, and spaced apart from the first portion, and a third portion connected to the first portion and the second portion, and including the second semiconductor layer.

The organic layer may be between the first portion and the second portion.

The light-emitting element may further include a passivation layer on an outer surface of the first portion, on an outer surface of the second portion, and on a side surface of the third portion.

The first connection electrode may be on an outer surface of the first portion, and on a part of a side surface of the third portion, wherein the second connection electrode is on an outer surface of the second portion and another part of the side surface of the third portion.

According to one or more embodiments of the present disclosure, there is provided a method for manufacturing a display device, the method including forming pixel electrodes on a substrate, forming an adhesive layer covering the pixel electrodes, fixing light-emitting elements to the adhesive layer, forming an organic layer by removing a part of the adhesive layer to expose edges of top surfaces of the pixel electrodes, forming connection electrodes respectively connecting the pixel electrodes to contact electrodes of the light-emitting elements, and forming a common electrode on a top surface of each of the light-emitting elements.

The forming of the pixel electrodes on the substrate, and the forming of the adhesive layer covering the pixel electrodes, may include using a mask.

The forming of the connection electrodes respectively connecting the pixel electrodes to the contact electrodes of the light-emitting elements may include forming a first connection electrode layer covering the pixel electrodes, the organic layer, and the light-emitting elements, forming a second connection electrode layer by removing a part of the first connection electrode layer using the mask, forming a bank covering edges of the pixel electrodes, forming a third organic layer covering the bank, and forming the connection electrodes by etching a second connection electrode layer exposed without being covered by the third organic layer.

According to the aforementioned and other embodiments of the present disclosure, an adhesive layer (or a temporary adhesive layer or a temporary fixing layer) is formed on pixel electrodes, and the adhesive layer is completely cured after a portion of each of a plurality of light-emitting elements is embedded in the adhesive layer, thereby fixing the plurality of light-emitting elements to the adhesive layer. Therefore, in a process of transferring the plurality of light-emitting elements to the display panel, it is possible to reduce or prevent the likelihood of the plurality of light-emitting elements tilting or falling. Accordingly, it is possible to reduce or prevent each of the plurality of light-emitting elements from becoming unable to be electrically connected to the pixel electrode.

### BRIEF DESCRIPTION OF THE DRAWINGS

The above and other aspects of the present disclosure will become more apparent by describing embodiments thereof with reference to the attached drawings, in which:

FIG. 1 is a perspective view illustrating a display device according to one or more embodiments;

FIG. 2 is a layout view illustrating a display device according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is an equivalent circuit diagram illustrating a sub-pixel according to one or more other embodiments;

FIG. 6 is a layout view illustrating pixels of a display area according to one or more embodiments;

FIG. 7 is a cross-sectional view showing the display panel taken along the line I1-I1′ of FIG. 6;

FIG. 8 is a cross-sectional view illustrating an example of area A of FIG. 7;

FIG. 9 is a cross-sectional view showing another example of area A of FIG. 7;

FIG. 10 is a cross-sectional view showing still another example of area A of FIG. 7;

FIG. 11 is a cross-sectional view showing the display panel taken along the line I1-I1′ of FIG. 6;

FIG. 12 is a plan view illustrating an example of area B of FIG. 11;

FIG. 13 is a cross-sectional view showing another example of area B of FIG. 11;

FIG. 14 is a cross-sectional view showing still another example of area B of FIG. 11;

FIG. 15 is a cross-sectional view showing the display panel taken along the line I1-I1′ of FIG. 6;

FIG. 16 is a cross-sectional view illustrating an example of area C of FIG. 15;

FIG. 17 is a cross-sectional view showing another example of area C of FIG. 15;

FIG. 18 is a cross-sectional view showing still another example of area C of FIG. 15;

FIG. 19 is a layout view illustrating pixels of a display area according to one or more embodiments;

FIG. 20 is a cross-sectional view showing the display panel taken along the line I2-I2′ of FIG. 19;

FIG. 21 is a cross-sectional view illustrating an example of area D of FIG. 20;

FIG. 22 is a cross-sectional view showing another example of area D of FIG. 20;

FIG. 23 is a cross-sectional view showing still another example of area D of FIG. 20;

FIG. 24 is a cross-sectional view showing the display panel taken along the line I2-I2′ of FIG. 19;

FIG. 25 is a cross-sectional view illustrating an example of area E of FIG. 24;

FIG. 26 is a cross-sectional view showing still another example of area E of FIG. 24;

FIG. 27 is a cross-sectional view showing still another example of area E of FIG. 24;

FIG. 28 is a cross-sectional view showing the display panel taken along the line I2-I2′ of FIG. 19;

FIG. 29 is a cross-sectional view illustrating an example of area F of FIG. 28;

FIG. 30 is a cross-sectional view showing still another example of area F of FIG. 28;

FIG. 31 is a cross-sectional view showing still another example of area F of FIG. 28;

FIG. 32 is a flowchart illustrating a method for manufacturing a display device according to one or more embodiments;

FIGS. 33 to 41 are cross-sectional views illustrating a method for manufacturing a display device according to one or more embodiments;

FIG. 42 is a diagram illustrating a virtual reality device including a display device according to one or more embodiments;

FIG. 43 is a diagram illustrating a smart watch including a display device according to one or more embodiments;

FIG. 44 is a diagram illustrating a dashboard of an automobile and a center fascia including display devices according to one or more embodiments; and

FIG. 45 is a diagram illustrating a transparent display device including a display device according to one or more embodiments.

### DETAILED DESCRIPTION

Aspects of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions, such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression, such as “at least one of A and/or B” may include A, B, or A and B. As used herein, the term “and/or” includes any and all combinations of one or more of the associated listed items. For example, the expression, such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

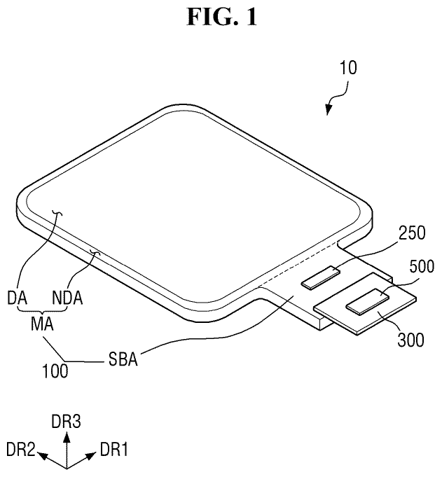

FIG. 1 is a perspective view illustrating a display device according to one or more embodiments.

Referring to FIG. 1, a display device 10 is a device for displaying a moving image or a still image. The display device 10 may be used as a display screen of various devices, such as a television, a laptop computer, a monitor, a billboard and an Internet-of-Things (IoT) device, as well as portable electronic devices, such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light-emitting display device, such as an organic light-emitting display using an organic light-emitting diode, a quantum dot light-emitting display including a quantum dot light-emitting layer, an inorganic light-emitting display including an inorganic semiconductor, and a micro light-emitting display using a micro or nano light-emitting diode (LED). In the following description, it is assumed that the display device 10 is a micro light-emitting display device, but the present disclosure is not limited thereto. Meanwhile, for simplicity of description, an ultra-small light-emitting diode is referred to hereafter as a light-emitting element.

The display device 10 includes a display panel 100, a display-driving circuit 250, a circuit board 300, and a power supply circuit 500.

The display panel 100, in plan view, may be formed in a rectangular shape having short sides in a first direction DR1, and long sides in a second direction DR2 crossing the first direction DR1. The corner where the short side in the first direction DR1 and the long side in the second direction DR2 meet may be rounded to have a curvature (e.g., predetermined curvature) or may be right-angled. The planar shape of the display panel 100 is not limited to the rectangular shape, and may be formed in another polygonal shape, a circular shape or an elliptical shape. The display panel 100 may be formed to be flat, but is not limited thereto. For example, the display panel 100 may include a curved portion formed at left and right ends and having a constant curvature or a varying curvature. In addition, the display panel 100 may be formed flexibly so that it can be curved, bent, folded, or rolled.

A substrate SUB of the display panel 100 may include a main region MA and a sub-region SBA.

The main region MA may include a display area DA for displaying an image, and a non-display area NDA that is a peripheral area of the display area DA. The display area DA may include a plurality of pixels displaying an image. For example, the pixel may include a first sub-pixel that emits first light, a second sub-pixel that emits second light, and a third sub-pixel that emits third light.

The sub-region SBA may protrude from one side of the main region MA in the second direction DR2. Although it is shown in FIG. 1 that the sub-region SBA is unfolded, the sub-region SBA may be bent and, in this case, may be arranged on the bottom surface of the display panel 100. In the case where the sub-region SBA is bent, it may overlap the main region MA in a third direction DR3 that is a thickness direction of the display panel 100. The display-driving circuit 250 may be arranged in the sub-region SBA.

The display-driving circuit 250 may generate signals and voltages for driving the display panel 100. The display-driving circuit 250 may be formed as an integrated circuit (IC) and attached onto the display panel 100 by a chip-on-glass (COG) method, a chip-on-plastic (COP) method, or an ultrasonic bonding method, but the present disclosure is not limited thereto. For example, the display-driving circuit 250 may be attached onto the circuit board 300 by a chip-on-film (COF) method.

The circuit board 300 may be attached to one end of the sub-region SBA of the display panel 100. Thus, the circuit board 300 may be electrically connected to the display panel 100 and the display-driving circuit 250. The display panel 100 and the display-driving circuit 250 may receive digital video data, timing signals, and driving voltages through the circuit board 300. The circuit board 300 may be a flexible printed circuit board, a printed circuit board, or a flexible film, such as a chip on film.

The power supply circuit 500 may generate a plurality of panel driving voltages according to a power voltage from the outside. The power supply circuit 500 may be formed as an integrated circuit (IC) and attached to the circuit board 300 by a COF method.

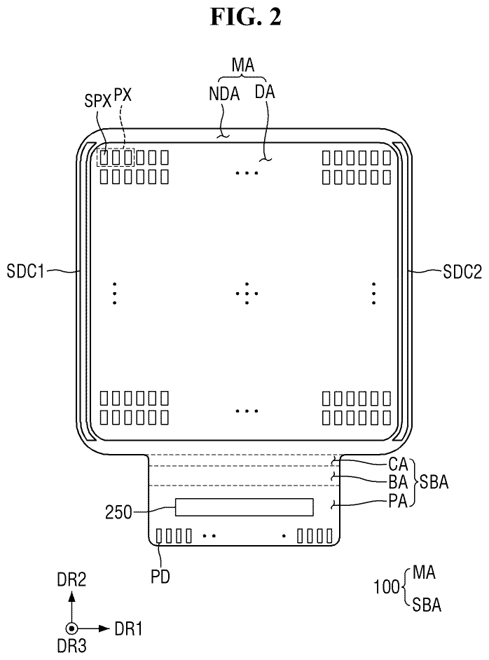

FIG. 2 is a layout view illustrating a display device according to one or more embodiments. It is shown in FIG. 2 that the sub-region SBA is unfolded without being bent.

Referring to FIG. 2, the display panel 100 may include the main region MA and the sub-region SBA.

The main region MA may include the display area DA displaying an image and the non-display area NDA that is a peripheral area of the display area DA. The display area DA may occupy most of the main region MA. The display area DA may be located at the center of the main region MA.

The display area DA may include a plurality of pixels PX for displaying an image, and each of the plurality of pixels PX may include a plurality of sub-pixels SPX. The pixel PX may be defined as a minimum unit sub-pixel group capable of expressing a white grayscale.

The non-display area NDA may be located adjacent to the display area DA. The non-display area NDA may be an area outside the display area DA. The non-display area NDA may surround the display area DA. The non-display area NDA may be an edge area of the display panel 100.

A first scan driver SDC1 and a second scan driver SDC2 may be located in the non-display area NDA. The first scan driver SDC1 may be located at one side (for example, left side) of the display panel 100, and the second scan driver SDC2 may be located at the other side (for example, right side) of the display panel 100, but the present disclosure is not limited thereto. Each of the first scan driver SDC1 and the second scan driver SDC2 may be electrically connected to the display-driving circuit 250 through scan fan-out lines. Each of the first scan driver SDC1 and the second scan driver SDC2 may receive scan control signals inputted from the display-driving circuit 250, may generate scan signals in response to the scan control signals, and may output the generated scan signals to scan lines.

The sub-region SBA may protrude from one side of the main region MA in the second direction DR2. The length of the sub-region SBA in the second direction DR2 may be less than the length of the main region MA in the second direction DR2. The length of the sub-region SBA in the first direction DR1 may be substantially equal to or less than the length of the main region MA in the first direction DR1. The sub-region SBA may be foldable to be located under the display panel 100. In this case, the sub-region SBA may overlap the main region MA in the third direction DR3.

The sub-region SBA may include a connection area CA, a pad area PA, and a bending area BA.

The connection area CA is an area protruding from one side of the main region MA in the second direction DR2. One side of the connection area CA may be in contact with the non-display area NDA of the main region MA, and the other side of the connection area CA may be in contact with the bending area BA.

The pad area PA is an area on which pads PD and the display-driving circuit 250 are located. The display-driving circuit 250 may be attached to driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may be in contact with the bending area BA.

The bending area BA is an area being bent. When the bending area BA is bent, the pad area PA may be located under the connection area CA and the main region MA. The bending area BA may be located between the connection area CA and the pad area PA. One side of the bending area BA may be in contact with the connection area CA, and the other side of the bending area BA may be in contact with the pad area PA.

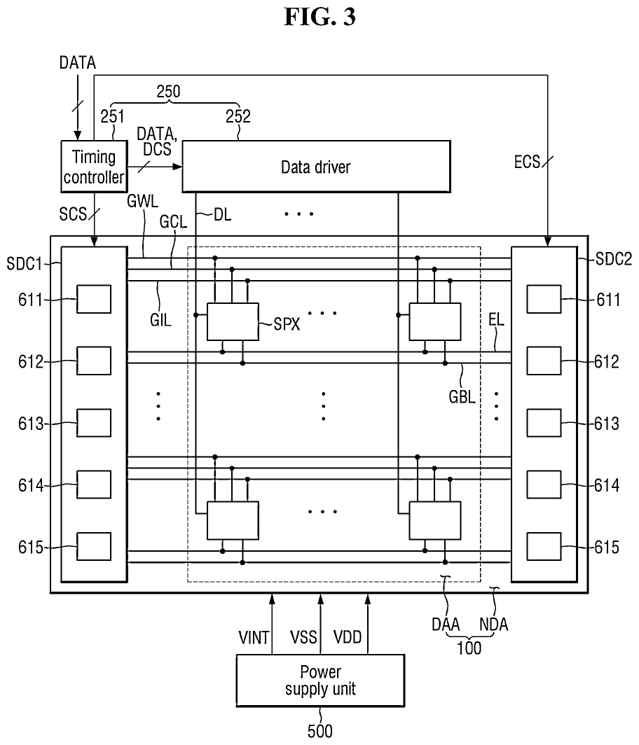

FIG. 3 is a block diagram illustrating a display device according to one or more embodiments.

Referring to FIG. 3, the display area DA includes the plurality of pixels PX, a plurality of scan lines, a plurality of emission control lines EL, and a plurality of data lines DL.

The plurality of pixels PX may be arranged in a matrix form in the first direction DR1 and the second direction DR2. The plurality of scan lines and the plurality of emission control lines EL may extend in the first direction DR1, while being arranged in the second direction DR2. The plurality of data lines DL may extend in the second direction DR2, while being arranged in the first direction DR1. The plurality of scan lines include a plurality of write scan lines GWL, a plurality of control scan lines GCL, a plurality of initialization scan lines GIL, and a plurality of bias scan lines GBL.

Each of the plurality of sub-pixels SPX may be connected to any one write scan line GWL among the plurality of write scan lines GWL, any one control scan line GCL among the plurality of control scan lines GCL, any one initialization scan line GIL among the plurality of initialization scan line GIL, any one bias scan line GBL among the plurality of bias scan lines GBL, any one emission control line EL among the plurality of emission control lines EL, and any one data line DL among the plurality of data lines DL. Each of the plurality of sub-pixels SPX may receive the data voltage of the data line DL according to the write scan signal of the write scan line GWL, and may emit light from a light-emitting element thereof according to the data voltage.

The non-display area NDA includes the first scan driver SDC1, the second scan driver SDC2, and the display-driving circuit 250.

Each of the first scan driver SDC1 and the second scan driver SDC2 may include a write scan signal output unit 611, a control scan signal output unit 612, an initialization scan signal output unit 613, a bias scan signal output unit 614, and an emission signal output unit 615. Each of the write scan signal output unit 611, the control scan signal output unit 612, the initialization scan signal output unit 613, the bias scan signal output unit 614, and the emission signal output unit 615 may receive a scan-timing-control signal SCS from a timing control circuit 400. The write scan signal output unit 611 may generate write scan signals according to the scan-timing-control signal SCS of the timing control circuit 400, and may output them sequentially to the write scan lines GWL. The control scan signal output unit 612 may generate control scan signals in response to the scan-timing-control signal SCS, and may sequentially output them to the control scan lines GCL. The initialization scan signal output unit 613 may generate initialization scan signals in response to the scan-timing-control signal SCS, and may sequentially output them to the initialization scan lines GIL. The bias scan signal output unit 614 may generate bias scan signals according to the scan-timing-control signal SCS, and may output them sequentially to bias scan lines EBL. The emission signal output unit 615 may generate emission control signals according to the scan-timing-control signal SCS and sequentially output them to the emission control lines EL.

The display-driving circuit 250 includes a timing control circuit 251 and a data-driving circuit 252.

The data-driving circuit 252 may receive the digital video data DATA and the data-timing-control signal DCS from the timing control circuit 251. The data-driving circuit 252 converts the digital video data DATA into analog data voltages in response to the data-timing-control signal DCS, and outputs them to the data lines DL. In this case, the sub-pixels SPX may be selected by the write scan signal of the first scan driver SDC1 and the second scan driver SDC2, and data voltages may be supplied to the selected sub-pixels SPX.

The timing control circuit 251 may receive digital video data and timing signals from the outside. The timing control circuit 251 may generate the scan-timing-control signal SCS and a data-timing-control signal DCS for controlling the display panel 100 in response to the timing signals. The timing control circuit 400 may output the scan-timing-control signal SCS to the first scan driver SDC1 and the second scan driver SDC2. The timing control circuit 251 may output the digital video data DATA and the data-timing-control signal DCS to the data-driving circuit 252.

The power supply circuit 500 may generate a plurality of panel driving voltages according to a power voltage from the outside. For example, the power supply circuit 500 may generate a first driving voltage VDD, a second driving voltage VSS, and a third driving voltage VINT and supply them to the display panel 100.

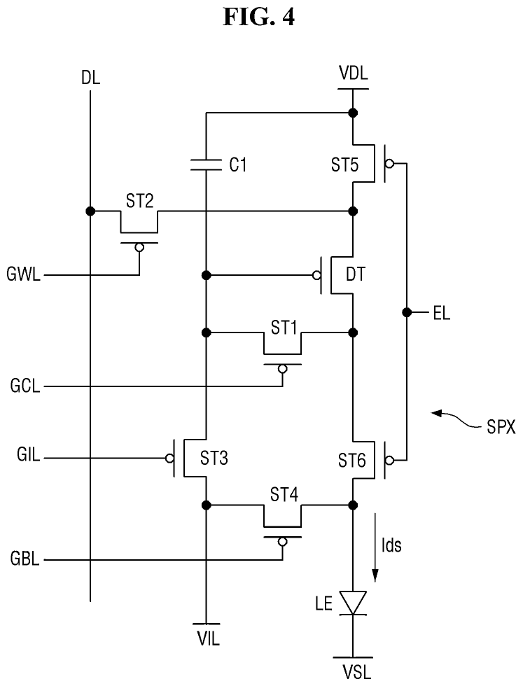

FIG. 4 is an equivalent circuit diagram illustrating a sub-pixel according to one or more embodiments.

Referring to FIG. 4, the sub-pixel SPX according to one or more embodiments may be connected to the scan lines GWL, GIL, GCL, and GBL, the emission line EL, and the data line DL. For example, the sub-pixel SPX may be connected to the write scan line GWL, the initialization scan line GIL, the control scan line GCL, the bias scan line GBL, the emission line EL, and the data line DL.

The sub-pixel SPX according to one or more embodiments includes a driving transistor DT, switch elements, a capacitor C1, and a light-emitting element LE. The switch elements include the first to sixth transistors ST1, ST2, ST3, ST4, ST5, and ST6.

The driving transistor DT includes a gate electrode, a first electrode, and a second electrode. The driving transistor DT controls a drain-source current Ids (hereinafter, referred to as “driving current”) flowing between the first electrode and the second electrode according to a data voltage applied to the gate electrode.

The light-emitting element LE may be a micro light-emitting diode element. The light-emitting element LE may emit light according to a driving current Ids. The emission amount of the light-emitting element LE may be proportional to the driving current Ids. The anode electrode of the light-emitting element LE may be connected to the first electrode of the fourth transistor ST4 and the second electrode of the sixth transistor ST6, and the cathode electrode thereof may be connected to a second power line VSL to which a second power voltage is applied.

The capacitor C1 is formed between the second electrode of the driving transistor DT and a first power line VDL to which a first power voltage is applied. The first power voltage may be the voltage having a level higher than that of the second power voltage. One electrode of the capacitor C1 may be connected to the second electrode of the driving transistor DT, and the other electrode thereof may be connected to the first power line VDL.

As shown in FIG. 4, the first to sixth transistors ST1, ST2, ST3, ST4, ST5, and ST6, and the driving transistor DT may all be formed as p-type MOSFETs. In this case, the active layer of each of the driving transistor DT and the first to sixth transistors ST1, ST2, ST3, ST4, ST5, and ST6 may be formed of polysilicon.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFETs, they may be turned on when a scan signal and an emission signal of a gate low voltage are applied to the control scan line GCL, the initialization scan line GIL, and the write scan line GWL, the bias scan line GBL, and the emission line EL. One electrode of the third transistor ST3 and one electrode of the fourth transistor ST4 may be connected to the initialization voltage line VIL.

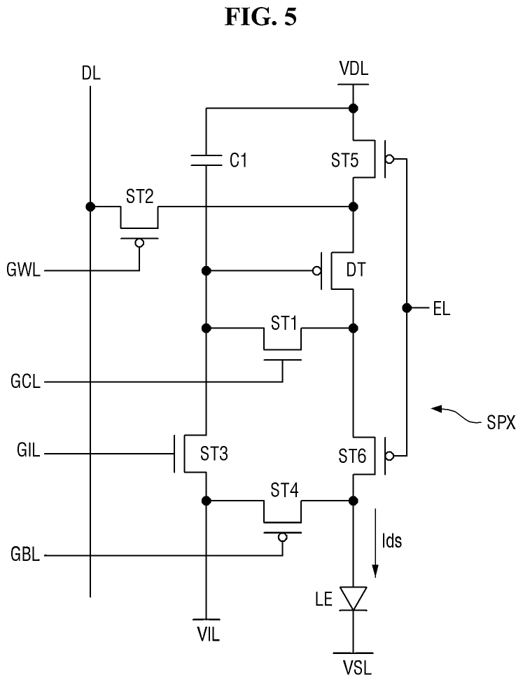

FIG. 5 is an equivalent circuit diagram illustrating a sub-pixel according to one or more other embodiments.

Referring to FIG. 5, the driving transistor DT, the second transistor ST2, the fourth transistor ST4, the fifth transistor ST5, and the sixth transistor ST6 may be configured as p-type metal oxide semiconductor field effect transistors (MOSFETs), and the first transistor ST1 and the third transistor ST3 may be configured as n-type MOSFETs. An active layer of each of the driving transistor DT, the second transistor ST2, the fourth transistor ST4, the fifth transistor ST5 and the sixth transistor ST6 configured as the P-type MOSFETs may be formed of polysilicon, whereas an active layer of each of the first transistor ST1 and the third transistor ST3 configured as the N-type MOSFETs may be formed of an oxide semiconductor. In this case, the transistors formed of polysilicon and the transistors formed of an oxide semiconductor may be located on different layers.

Because the first transistor ST1 and the third transistor ST3 are formed as n-type MOSFETs, the first transistor ST1 may be turned on when the control scan signal of a gate high voltage is applied to the control scan line GCL, and the third transistor ST3 may be turned on when the initialization scan signal is applied to the initialization scan line GIL. In contrast, because the second transistor ST2, the fourth transistor ST4, the fifth transistor ST5, and the sixth transistor ST6 are formed as p-type MOSFETs, they may be turned on when the emission signal and the scan signal of a gate low voltage are applied to each of the write scan line GWL, the bias scan line GBL, and the emission line EL.

Alternatively, in FIG. 4, the fourth transistor ST4 may be formed as an n-type MOSFET. In this case, the active layer of the fourth transistor ST4 may also be formed of an oxide semiconductor. When the fourth transistor ST4 is formed as an n-type MOSFET, it may be turned on when the bias scan signal of a gate high voltage is applied to the bias scan line GBL.

Alternatively, in one or more embodiments, the first to sixth transistors ST1, ST2, ST3, ST4, ST5, and ST6 and the driving transistor DT may all be formed as n-type MOSFETs. In this case, the active layer of each of the driving transistor DT and the first to sixth transistors ST1, ST2, ST3, ST4, ST5, and ST6 may be formed of an oxide semiconductor.

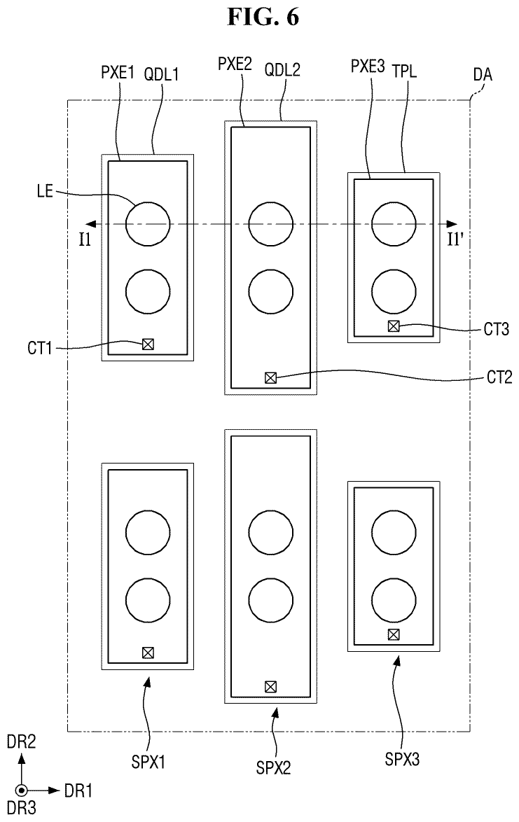

FIG. 6 is a layout view illustrating pixels of a display area according to one or more embodiments.

Referring to FIG. 6, each of the plurality of pixels PX in the display area DA may include a first sub-pixel SPX1, a second sub-pixel SPX2, and a third sub-pixel SPX3.

The plurality of pixels PX may be arranged in a matrix. In each of the plurality of pixels PX, the first sub-pixel SPX1, the second sub-pixel SPX2, and the third sub-pixel SPX3 may be arranged in the first direction DR1.

The first sub-pixel SPX1 may emit first light, the second sub-pixel SPX2 may emit second light, and the third sub-pixel SPX3 may emit third light. Here, the first light may be light of a red wavelength band, the second light may be light of a green wavelength band, and the third light may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm. However, the present disclosure is not limited thereto, and each of the first sub-pixel SPX1, the second sub-pixel SPX2, and the third sub-pixel SPX3 may emit any one of first light, second light, or third light.

The first sub-pixel SPX1 includes a first pixel electrode PXE1, a plurality of light-emitting elements LE, and a first light conversion layer QDL1. The second sub-pixel SPX2 includes a second pixel electrode PXE2, a plurality of light-emitting elements LE, and a second light conversion layer QDL2. The third sub-pixel SPX3 includes a third pixel electrode PXE3, a plurality of light-emitting elements LE, and a light-transmitting layer TPL.

The light-emitting elements LE of the first sub-pixel SPX1, the light-emitting elements LE of the second sub-pixel SPX2, and the light-emitting elements LE of the third sub-pixel SPX3 emit light in a blue wavelength band, the first light conversion layer QDL1 and the second light conversion layer QDL2 are suitable for wavelength conversion. However, the present disclosure is not limited thereto, and when the light-emitting elements LE of the first sub-pixel SPX1 emit light of a first color, the light-emitting elements LE of the second sub-pixel SPX2 emit light of a second color, and the light-emitting elements LE of the third sub-pixel SPX3 emit light of a third color, the first light conversion layer QDL1, the second light conversion layer QDL2, and the light-transmitting layer TPL may be omitted. Each of the first pixel electrode PXE1, the second pixel electrode PXE2, and the third pixel electrode PXE3 may have a rectangular planar shape having short sides in the first direction DR1 and long sides in the second direction DR2. The area of the first sub-pixel SPX1, the area of the second sub-pixel SPX2, and the area of the third sub-pixel SPX3 may be set depending on the light conversion efficiency of the first light conversion layer QDL1 and the light conversion efficiency of the second light conversion layer QDL2.

For example, as shown in FIG. 6, the area of the second pixel electrode PXE2 may be larger than the area of the first pixel electrode PXE1, and the area of the first pixel electrode PXE1 may be larger than the area of the third pixel electrode PXE3. When the length of the first pixel electrode PXE1 in the first direction DR1, the length of the second pixel electrode PXE2 in the first direction DR1, and the length of the third pixel electrode PXE3 in the first direction DR1 are the same, the length of the second pixel electrode PXE2 in the second direction DR2 may be longer than the length of the first pixel electrode PXE1 in the second direction DR2, and the length of the first pixel electrode PXE1 in the second direction DR2 may be longer than the length of the third pixel electrode PXE3 in the second direction DR2. However, the present disclosure is not limited thereto, and the length of the first pixel electrode PXE1 in the first direction DR1, the length of the second pixel electrode PXE2 in the first direction DR1, and the length of the third pixel electrode PXE3 in the first direction DR1 may be the same, and the length of the first pixel electrode PXE1 in the second direction DR2, the length of the second pixel electrode PXE2 in the second direction DR2, and the length of the third pixel electrode PXE3 in the second direction DR2 may be different. Alternatively, the length of the first pixel electrode PXE1 in the second direction DR2, the length of the second pixel electrode PXE2 in the second direction DR2, and the length of the third pixel electrode PXE3 in the second direction DR2 may be the same, and the length of the first pixel electrode PXE1 in the first direction DR1, the length of the second pixel electrode PXE2 in the first direction DR1, and the length of the third pixel electrode PXE3 in the first direction DR1 may be different. Alternatively, the length of the first pixel electrode PXE1 in the first direction DR1, the length of the second pixel electrode PXE2 in the first direction DR1, the length of the third pixel electrode PXE3 in the first direction DR1, the length of the first pixel electrode PXE1 in the second direction DR2, the length of the second pixel electrode PXE2 in the second direction DR2, and the length of the third pixel electrode PXE3 in the second direction DR2 may be the same. Alternatively, the length in the first direction DR1 and the length in the second direction DR2 of any two pixel electrodes among the first pixel electrode PXE1, the second pixel electrode PXE2, or the third pixel electrode PXE3 may be the same, and the length in the first direction DR1 and the length in the second direction DR2 of the other one pixel electrode may be different from the length in the first direction DR1 and the length in the second direction DR2 of the any two pixel electrodes.

The first pixel electrode PXE1 may be electrically connected to the second electrode of the fourth transistor ST4 (see FIGS. 4 and 5) of the first sub-pixel SPX1 and to the second electrode of the sixth transistor ST6 (see FIGS. 4 and 5) thereof through a first connection hole CT1. The second pixel electrode PXE2 may be electrically connected to the second electrode of the fourth transistor ST4 (see FIGS. 4 and 5) of the second sub-pixel SPX2 and to the second electrode of the sixth transistor ST6 (see FIGS. 4 and 5) thereof through a second connection hole CT2. The third pixel electrode PXE3 may be electrically connected to the second electrode of the fourth transistor ST4 (see FIGS. 4 and 5) of the third sub-pixel SPX3 and to the second electrode of the sixth transistor ST6 (see FIGS. 4 and 5) thereof through a third connection hole CT3.

The plurality of light-emitting elements LE may be located on each of the first pixel electrode PXE1, the second pixel electrode PXE2, and the third pixel electrode PXE3. The same number of light-emitting elements LE may be located on each of the first pixel electrode PXE1, the second pixel electrode PXE2, and the third pixel electrode PXE3. For example, two light-emitting elements LE may be located on each of the first pixel electrode PXE1, the second pixel electrode PXE2, and the third pixel electrode PXE3. The plurality of light-emitting elements LE may emit third light, that is, light in a blue wavelength band.

However, the present disclosure is not limited thereto, and one light-emitting element LE may be located on each of the first pixel electrode PXE1, the second pixel electrode PXE2, and the third pixel electrode PXE3, or two or more light-emitting elements LE, for example, three light-emitting elements LE or four light-emitting elements LE may be located thereon. When two or more light-emitting elements LE are located on each of the first pixel electrode PXE1, the second pixel electrode PXE2, and the third pixel electrode PXE3, even if contact failure occurs between one of the light-emitting elements LE and the pixel electrode, the other light-emitting elements LE may emit light by the contact with the pixel electrode, which is advantageous in that repair is not required.

The first light conversion layer QDL1 may completely overlap the first pixel electrode PXE1 and the plurality of light-emitting elements LE of the first sub-pixel SPX1. The area of the first light conversion layer QDL1 may be larger than the area of the first pixel electrode PXE1. The first light conversion layer QDL1 may emit light by converting or shifting the peak wavelength of incident light to another corresponding peak wavelength. For example, the first light conversion layer QDL1 may convert or shift the third light emitted from the plurality of light-emitting elements LE of the first sub-pixel SPX1 into the first light.

The second light conversion layer QDL2 may completely overlap the plurality of light-emitting elements LE of the second sub-pixel SPX2 and the second pixel electrode PXE2. The area of the second light conversion layer QDL2 may be larger than the area of the second pixel electrode PXE2. The second light conversion layer QDL2 may emit light by converting or shifting the peak wavelength of incident light to another corresponding peak wavelength. For example, the second light conversion layer QDL2 may convert or shift the third light emitted from the plurality of light-emitting elements LE of the second sub-pixel SPX2 into the second light.

The light-transmitting layer TPL may completely overlap the plurality of light-emitting elements LE of the third sub-pixel SPX3 and the third pixel electrode PXE3.

The light-transmitting layer TPL may directly transmit incident light. For example, the light-transmitting layer TPL may directly transmit the third light emitted from the plurality of light-emitting elements LE of the third sub-pixel SPX3.

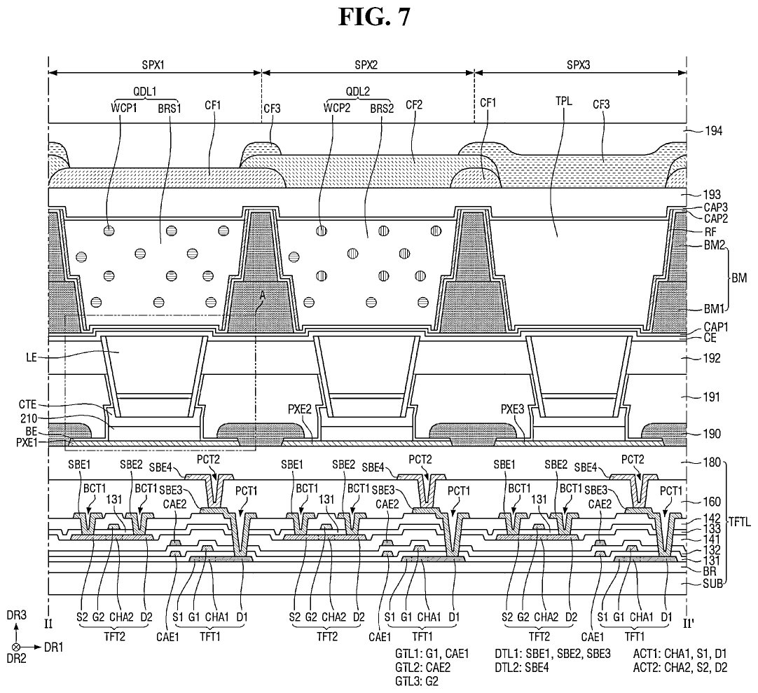

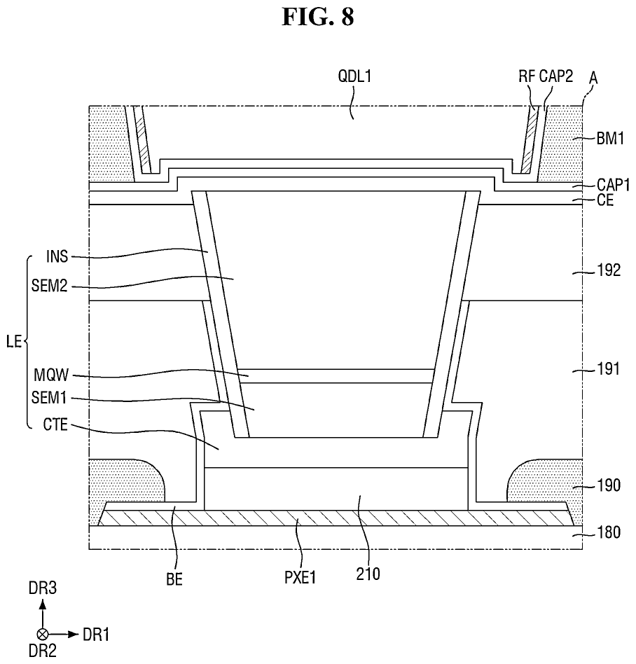

FIG. 7 is a cross-sectional view showing the display panel taken along the line I1-I1′ of FIG. 6. FIG. 8 is a cross-sectional view illustrating an example of area A of FIG. 7.

Referring to FIGS. 7 and 8, the substrate SUB may be made of an insulating material, such as glass or polymer resin. When the substrate SUB is made of polymer resin, it may be a flexible substrate that can be stretched. The polymer resin may include acryl resin, epoxy resin, phenolic resin, polyamide resin, or polyimide resin.

The barrier layer BR may be located on the substrate SUB. The barrier layer BR is a layer for protecting transistors of the thin film transistor layer TFTL and a light-emitting layer 172 of the light-emitting element layer EML from moisture permeating through the substrate SUB which is susceptible to moisture permeation. The barrier layer BR may be formed as a plurality of inorganic layers that are alternately stacked. For example, the barrier layer BR may be formed of multiple layers in which one or more inorganic layers of a silicon nitride layer, a silicon oxynitride layer, a silicon oxide layer, a titanium oxide layer and an aluminum oxide layer are alternately stacked.

A first thin film transistor TFT1 may be located on the barrier layer BR. The first thin film transistor TFT1 may be any one of the fourth transistor ST4 or the sixth transistor ST6 shown in FIG. 5. The first thin film transistor TFT1 may include a first active layer ACT1 and a first gate electrode G1.

The first active layer ACT1 of the first thin film transistor TFT1 may be located on the barrier layer BR. The first active layer ACT1 of the first thin film transistor TFT1 may include polycrystalline silicon, monocrystalline silicon, low-temperature polycrystalline silicon, or amorphous silicon.

The first active layer ACT1 may include a first channel region CHA1, a first source region S1, and a first drain region D1. The first channel region CHA1 may be a region overlapping the first gate electrode G1 in the third direction DR3 that is the thickness direction of the substrate SUB. The first source region S1 may be located on one side of the first channel region CHA1, and the first drain region D1 may be located on the other side of the first channel region CHA1. The first source region S1 and the first drain region D1 may be regions that do not overlap the first gate electrode G1 in the third direction DR3. The first source region S1 and the first drain region D1 may be regions having conductivity by doping a silicon semiconductor with ions.

A first gate-insulating layer 131 may be located on the first channel region CHA1, the first source region S1, and the first drain region D1 of the first thin film transistor TFT1. The first gate-insulating layer 131 may be formed of an inorganic layer, for example, a silicon nitride layer, a silicon oxynitride layer, a silicon oxide layer, a titanium oxide layer, or an aluminum oxide layer.

A first gate metal layer GTL1 may be located on the first gate-insulating layer 131. The first gate metal layer GTL1 may include the first gate electrode G1, and the first capacitor electrode CAE1 of the first thin film transistor TFT1. The first gate electrode G1 may overlap the first active layer ACT1 in the third direction DR3. FIG. 7 illustrates that the first gate electrode G1 and the first capacitor electrode CAE1 are spaced apart from each other, but the first gate electrode G1 and the first capacitor electrode CAE1 may be connected to each other. The first gate metal layer GTL1 may be formed as a single layer or multiple layers made of any one of molybdenum (Mo), aluminum (Al), chromium (Cr), gold (Au), titanium (Ti), nickel (Ni), neodymium (Nd), or copper (Cu), or an alloy thereof.

A second gate-insulating layer 132 may be located on the first gate electrode G1 and the first capacitor electrode CAE1 of the first thin film transistor TFT1. The second gate-insulating layer 132 may be formed of an inorganic layer, for example, a silicon nitride layer, a silicon oxynitride layer, a silicon oxide layer, a titanium oxide layer, or an aluminum oxide layer.

A second gate metal layer GTL2 may be located on the second gate-insulating layer 132. The second gate metal layer GTL2 may include a second capacitor electrode CAE2. The second capacitor electrode CAE2 may overlap the first capacitor electrode CAE1 of the first thin film transistor TFT1 in the third direction DR3. Because the second gate-insulating layer 132 has a dielectric constant (e.g., predetermined dielectric constant), the capacitor C1 (FIG. 5) may be formed by the first capacitor electrode CAE1, the second capacitor electrode CAE2, and the second gate-insulating layer 132 located therebetween. The second gate metal layer GTL2 may be formed as a single layer or multiple layers made of any one of molybdenum (Mo), aluminum (Al), chromium (Cr), gold (Au), titanium (Ti), nickel (Ni), neodymium (Nd), or copper (Cu), or an alloy thereof.

A first interlayer insulating layer 141 may be located on the second capacitor electrode CAE2. The first interlayer insulating layer 141 may be formed of an inorganic layer, for example, a silicon nitride layer, a silicon oxynitride layer, a silicon oxide layer, a titanium oxide layer, or an aluminum oxide layer.

A second thin film transistor TFT2 may be located on the first interlayer insulating layer 141. The second thin film transistor TFT2 may be any one of the first transistor ST1 or the third transistor ST3 shown in FIG. 5. The second thin film transistor TFT2 may include the second active layer ACT2 and a second gate electrode G2.

The second active layer ACT2 of the second thin film transistor TFT2 may be located on the first interlayer insulating layer 141. The second active layer ACT2 may include an oxide semiconductor. For example, the second active layer ACT2 may be include IGZO (indium (In), gallium (Ga), zinc (Zn) and oxygen (O)), IGZTO (indium (In), gallium (Ga), zinc (Zn), tin (Sn) and oxygen (O)), or IGTO (indium (In), gallium (Ga), tin (Sn), or oxygen (O)).

The second active layer ACT2 may include a second channel region CHA2, a second source region S2, and a second drain region D2. The second channel region CHA2 may a region overlapping the second gate electrode G2 in the third direction DR3. The second source region S2 may be located on one side of the second channel region CHA2, and the second drain region D2 may be located on the other side of the second channel region CHA2. The second source region S2 and the second drain region D2 may be regions that do not overlap the second gate electrode G2 in the third direction DR3. The second source region S2 and the second drain region D2 may be regions having conductivity by doping an oxide semiconductor with ions.

A third gate-insulating layer 133 may be located on the second active layer ACT2 of the second thin film transistor TFT2. The third gate-insulating layer 133 may be formed of an inorganic layer, for example, a silicon nitride layer, a silicon oxynitride layer, a silicon oxide layer, a titanium oxide layer, or an aluminum oxide layer.

A third gate metal layer GTL3 may be located on the third gate-insulating layer 133. The third gate metal layer GTL3 may include the second gate electrode G2 of the second thin film transistor TFT2. The second gate electrode G2 may overlap the second active layer ACT2 in the third direction DR3. The third gate metal layer GTL3 may be formed as a single layer or multiple layers made of any one of molybdenum (Mo), aluminum (Al), chromium (Cr), gold (Au), titanium (Ti), nickel (Ni), neodymium (Nd), or copper (Cu), or an alloy thereof.

A second interlayer insulating layer 142 may be located on the second gate electrode G2 of the second thin film transistor TFT2. The second interlayer insulating layer 142 may be formed of an inorganic layer, for example, a silicon nitride layer, a silicon oxynitride layer, a silicon oxide layer, a titanium oxide layer, or an aluminum oxide layer.

The first data metal layer DTL1 may be located on the second interlayer insulating layer 142. The first data metal layer DTL1 may include a first source connection electrode SBE3, a second source connection electrode SBE1, and a third source connection electrode SBE2. The first source connection electrode SBE3 may be connected to the first drain region D of the first active layer ACT1 through a first source contact hole PCT1 penetrating the first gate-insulating layer 131, the second gate-insulating layer 132, the first interlayer insulating layer 141, the third gate-insulating layer 133, and the second interlayer insulating layer 142. The second source connection electrode SBE1 may be connected to the second source region S2 of the second active layer ACT2 through a second source connection contact hole BCT1 penetrating the second interlayer insulating layer 142. The third source connection electrode SBE2 may be connected to the second drain region D2 of the second active layer ACT2 through a third source connection contact hole BCT2 penetrating the second interlayer insulating layer 142. The first data metal layer DTL1 may be formed as a single layer or multiple layers made of any one of molybdenum (Mo), aluminum (Al), chromium (Cr), gold (Au), titanium (Ti), nickel (Ni), neodymium (Nd), or copper (Cu), or an alloy thereof. For example, the first data metal layer DTL1 may include a first layer made of titanium (Ti), a second layer made of aluminum (Al), and a third layer made of titanium (Ti).

A first organic layer 160 for flattening, or planarizing, the stepped portion caused by the first thin film transistor TFT1 and the second thin film transistor TFT2 may be located on the first source connection electrode SBE3, the second source connection electrode SBE1, and the third source connection electrode SBE2. The first organic layer 160 may be formed of an organic layer, such as acryl resin, epoxy resin, phenolic resin, polyamide resin, polyimide resin and the like.

The second data metal layer DTL2 may be located on the first organic layer 160. The second data metal layer DTL2 may include a fourth source connection electrode SBE4. The fourth source connection electrode SBE4 may be connected to the first source connection electrode SBE3 through a second pixel contact hole PCT2 penetrating the first organic layer 160. The second data metal layer DTL2 may be formed as a single layer or multiple layers made of any one of molybdenum (Mo), aluminum (Al), chromium (Cr), gold (Au), titanium (Ti), nickel (Ni), neodymium (Nd), or copper (Cu), or an alloy thereof. For example, the second data metal layer DTL2 may include a first layer made of titanium (Ti), a second layer made of aluminum (Al), and a third layer made of titanium (Ti).

A second organic layer 180 may be located on the fourth source connection electrode SBE4. The second organic layer 180 may be formed of an organic layer, such as acryl resin, epoxy resin, phenolic resin, polyamide resin, polyimide resin and the like.

The light-emitting element layer EML may be located on the second organic layer 180. The light-emitting element layer EML may include the pixel electrodes PXE1, PXE2, and PXE3, the light-emitting elements LE, a common electrode CE, and an organic layer 210.

A pixel electrode layer PXL may be located on the second organic layer 180. The pixel electrode layer PXL may include the first pixel electrode PXE1, the second pixel electrode PXE2, and the third pixel electrode PXE3. In the first sub-pixel SPX1, the first pixel electrode PXE1 may be connected to the fourth source connection electrode SBE4 through the first connection hole CT1 (see FIG. 6) penetrating the second organic layer 180. In the second sub-pixel SPX2, the second pixel electrode PXE2 may be connected to the fourth source connection electrode SBE4 through the second connection hole CT2 (see FIG. 6) penetrating the second organic layer 180. In the third sub-pixel SPX3, the third pixel electrode PXE3 may be connected to the fourth source connection electrode SBE4 through the third connection hole CT3 (see FIG. 6) penetrating the second organic layer 180.

In the first sub-pixel SPX1, the first pixel electrode PXE1 may be connected to the first source region S1 or the first drain region D1 of the first thin film transistor TFT1 through the first source connection electrode SBE3 and the fourth source connection electrode SBE4. Therefore, in the first sub-pixel SPX1, the voltage controlled by the first thin film transistor TFT1 may be applied to the first pixel electrode PXE1.

Further, in the second sub-pixel SPX2, the second pixel electrode PXE2 may be connected to the first source region S1 or the first drain region D1 of the first thin film transistor TFT1 through the first source connection electrode SBE3 and the fourth source connection electrode SBE4. Therefore, in the second sub-pixel SPX2, the voltage controlled by the first thin film transistor TFT1 may be applied to the second pixel electrode PXE2.

Further, in the third sub-pixel SPX3, the third pixel electrode PXE3 may be connected to the first source region S1 or the first drain region D1 of the first thin film transistor TFT1 through the first source connection electrode SBE3 and the fourth source connection electrode SBE4. Therefore, in the third sub-pixel SPX3, the voltage controlled by the first thin film transistor TFT1 may be applied to the third pixel electrode PXE3.

The pixel electrode layer PXL may be formed as a single layer or multiple layers made of any one of molybdenum (Mo), aluminum (Al), chromium (Cr), gold (Au), titanium (Ti), nickel (Ni), neodymium (Nd), or copper (Cu), or an alloy thereof. For example, to lower the resistance of each of the first pixel electrode PXE1, the second pixel electrode PXE2, and the third pixel electrode PXE3, the pixel electrode layer PXL may be formed as multiple layers made of copper (Cu) having a low sheet resistance, or an alloy of titanium (Ti) and copper (Cu).

A bank 190 may cover the edges of the first pixel electrode PXE1, the second pixel electrode PXE2, and the third pixel electrode PXE3. The bank 190 may be formed of an organic layer, such as acryl resin, epoxy resin, phenolic resin, polyamide resin, polyimide resin and the like. The bank 190 may include a light-blocking material to reduce or prevent light of the light-emitting element LE of any one sub-pixel traveling to the neighboring sub-pixel. For example, the bank 190 may contain an organic block pigment or an inorganic black pigment, such as carbon black or the like.

The organic layer 210 may be located on each of the first pixel electrode PXE1, the second pixel electrode PXE2, and the third pixel electrode PXE3. The organic layer 210 serves to temporarily fix or adhere the plurality of light-emitting elements LE to reduce or prevent the likelihood of them tilting or falling during the process of transferring the plurality of light-emitting elements LE to the display panel 100. That is, the organic layer 210 may be a layer for false adhesion of the plurality of light-emitting elements LE on each of the first pixel electrode PXE1, the second pixel electrode PXE2, and the third pixel electrode PXE3. To facilitate false adhesion, the thickness of the organic layer 210 may be greater than the thickness of each of the pixel electrodes PXE1, PXE2, and PXE3, and may be greater than the thickness of a contact electrode CTE.

The organic layer 210 may be a photosensitive organic layer, such as a photoresist. Alternatively, the organic layer 210 may be formed of acryl resin, epoxy resin, phenolic resin, polyamide resin, polyimide resin, or the like.

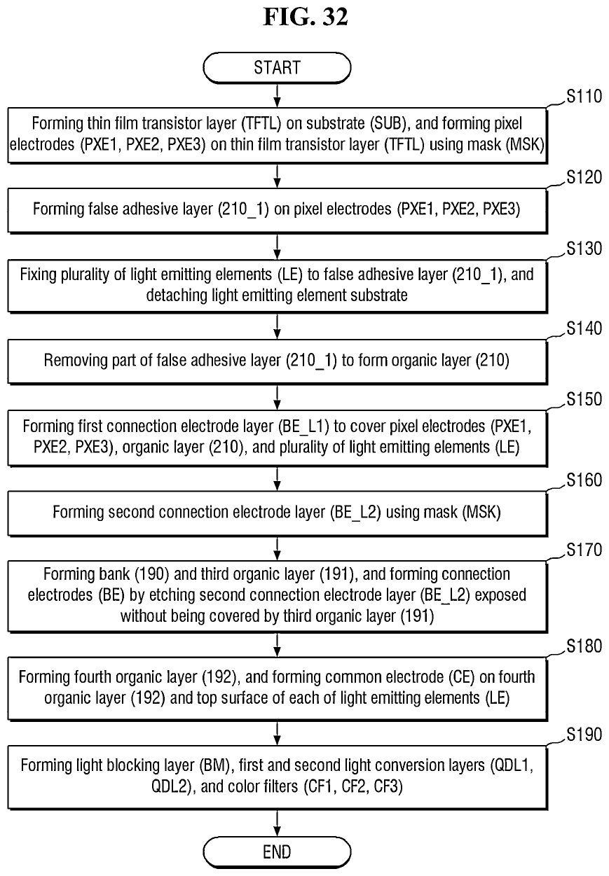

A detailed description of the organic layer 210 will be described later in conjunction with FIGS. 32 to 42.

The plurality of light-emitting elements LE may be located on the organic layer 210. FIG. 7 illustrates that each of the plurality of light-emitting elements LE is a vertical type micro LED extending in the third direction DR3. The vertical micro LED refers to an LED having a structure in which a first semiconductor layer SEM1, an active layer MQW, and a second semiconductor layer SEM2 are sequentially arranged in the third direction DR3 that is the vertical direction.

Each of the plurality of light-emitting elements LE may have a reverse tapered cross-sectional shape. That is, each of the plurality of light-emitting elements LE may have a trapezoidal cross-sectional shape in which the width of the top surface is wider than the width of the bottom surface. However, the present disclosure is not limited thereto, and each of the plurality of light-emitting elements LE may have a trapezoidal cross-sectional shape in which the width of the top surface is narrower than the width of the bottom surface, or may have a cross-sectional shape in which the width of the top surface and the width of the bottom surface are the same.

Each of the plurality of light-emitting elements LE may be made of an inorganic material, such as gallium nitride (GaN). Each of the plurality of light-emitting elements LE may have a length of several to several hundreds of μm in each of the first direction DR1, the second direction DR2, and the third direction DR3. For example, each of the plurality of light-emitting elements LE may have a length of about 100 μm or less in each of the first direction DR1, the second direction DR2, and the third direction DR.

Each of the plurality of light-emitting elements LE may be formed by growing on a semiconductor substrate, such as a silicon substrate or sapphire substrate. The plurality of light-emitting elements LE may be directly transferred from the semiconductor substrate onto the pixel electrodes PXE1, PXE2, and PXE3 of the display panel 100. Alternatively, the plurality of light-emitting elements LE may be transferred onto the pixel electrodes PXE1, PXE2, and PXE3 of the display panel 100 through an electrostatic method using an electrostatic head or a stamping method using an elastic polymer material, such as PDMS or silicon as a transfer substrate.

The light-emitting element LE may include the contact electrode CTE, the first semiconductor layer SEM1, the active layer MQW, the second semiconductor layer SEM2, and a passivation layer INS.

The contact electrode CTE may be located on the organic layer 210. The contact electrode CTE may be located on the entire bottom surface and a portion of the side surface of the first semiconductor layer SEM1. Further, the contact electrode CTE may be located on the passivation layer INS located on the side surface of the first semiconductor layer SEM1. The contact electrode CTE may include any one of molybdenum (Mo), aluminum (Al), chromium (Cr), gold (Au), titanium (Ti), nickel (Ni), neodymium (Nd), or copper (Cu).

The first semiconductor layer SEM1 may be located on the contact electrode CTE. The length in the first direction DR1 or the length in the second direction DR2 of the bottom surface of the first semiconductor layer SEM1 may be less than the length in the first direction DR1 or the length in the second direction DR2 of the contact electrode CTE. The first semiconductor layer SEM1 may be formed of GaN doped with a first conductivity type dopant, such as Mg, Zn, Ca, Se, or Ba.

The active layer MQW may be located on the first semiconductor layer SEM1. The active layer MQW may emit light by coupling of electron-hole pairs according to an electrical signal applied through the first semiconductor layer SEM1 and the second semiconductor layer SEM2.

The active layer MQW may include a material having a single or multiple quantum well structure. When the active layer MQW contains a material having a multiple quantum well structure, the active layer MQW may have the structure in which a plurality of well layers and barrier layers are alternately stacked. At this time, the well layer may be formed of InGaN, and the barrier layer may be formed of GaN or AlGaN, but the present disclosure is not limited thereto. Alternatively, the active layer MQW may have a structure in which semiconductor materials having large band gap energy and semiconductor materials having small band gap energy are alternately stacked, and may include other Group Ill, IV, or V semiconductor materials according to the wavelength band of the emitted light.

When the active layer MQW includes InGaN, the color of emitted light may vary depending on the content of indium (In). For example, as the content of indium (In) increases, the wavelength band of the light emitted by the active layer may shift to the red wavelength band, and as the content of indium (In) decreases, the wavelength band of the light emitted by the active layer may shift to the blue wavelength band. For example, the active layer MQW of the light-emitting element LE that emits the third light (light in the blue wavelength band) may contain about 10 wt % to 20 wt % of indium (In).

The second semiconductor layer SEM2 may be located on the first semiconductor layer SEM1. The second semiconductor layer SEM2 may be doped with a second conductive dopant, such as Si, Ge, Sn, or the like. For example, the second semiconductor layer SEM2 may be n-GaN doped with n-type Si.

The electron-blocking layer may be located between the first semiconductor layer SEM1 and the active layer MQW. The electron-blocking layer may be a layer for suppressing or preventing too many electrons from flowing into the active layer MQW. For example, the electron-blocking layer may be AlGaN or p-AlGaN doped with p-type Mg. The electron-blocking layer may be omitted.

The superlattice layer may be located between the active layer MQW and the second semiconductor layer SEM2. The superlattice layer may be a layer for relieving stress between the second semiconductor layer SEM2 and the active layer MQW. For example, the superlattice layer may be formed of InGaN or GaN. The superlattice layer may be omitted.

The passivation layer INS may be located on the side surface of the first semiconductor layer SEM1, the side surface of the active layer MQW, and the side surface of the second semiconductor layer SEM2. The passivation layer INS may be a layer for protecting the side surface of the light-emitting element LE. The passivation layer INS may be formed of an inorganic layer, for example, a silicon nitride layer, a silicon oxynitride layer, a silicon oxide layer, a titanium oxide layer, or an aluminum oxide layer.

A connection electrode BE connects the contact electrode CTE of the light-emitting element LE to a corresponding one of the first pixel electrode PXE1, the second pixel electrode PXE2, or the third pixel electrode PXE3. The connection electrode BE may be located on the top surface of the first pixel electrode PXE1, the second pixel electrode PXE2, or the third pixel electrode PXE3 that is exposed without being covered by the organic layer 210. Further, the connection electrode BE may be located on the side surface of the organic layer 210 and the side surface of the contact electrode CTE. Further, the connection electrode BE may be located on a portion of the side surface of the light-emitting element LE. For example, the connection electrode BE may be located on a portion of the passivation layer INS of the light-emitting element LE.

The connection electrode BE may include any one of molybdenum (Mo), aluminum (Al), chromium (Cr), gold (Au), titanium (Ti), nickel (Ni), neodymium (Nd), or copper (Cu). Alternatively, the connection electrode BE may be made of a transparent conductive material (TCO), such as indium tin oxide (ITO) or indium zinc oxide (IZO) capable of transmitting light.

When the connection electrode BE is made of a metal material having high reflectivity, such as aluminum (Al), the light traveling in the lateral direction of the light-emitting element LE among the light emitted from the active layer MQW of the light-emitting element LE may be reflected from the connection electrode BE, and may travel in the upward direction of the light-emitting element LE. Therefore, the loss of light from the light-emitting element LE may be reduced, which makes it possible to increase the light efficiency of the light-emitting element LE. The connection electrode BE may be formed as a single layer of a metal having high reflectivity, or may be formed as multiple layers, such as titanium (Ti)/aluminum (Al)/titanium (Ti) or ITO/aluminum (Al)/ITO.

A third organic layer 191 may cover the bank 190 and a portion of the side surface of each of the plurality of light-emitting element LE. Further, the third organic layer 191 covers the connection electrode BE, but at least a portion of the connection electrode BE may be exposed without being covered by the third organic layer 191. The third organic layer 191 may be formed of an organic layer, such as acryl resin, epoxy resin, phenolic resin, polyamide resin, polyimide resin and the like.

The fourth organic layer 192 may be located on the third organic layer 191. The fourth organic layer 192 may cover a portion of the side surface of each of the plurality of light-emitting elements LE. The fourth organic layer 192 may be located on at least a portion of the contact electrode CTE that is exposed without being covered by the third organic layer 191. The top surface of each of the plurality of light-emitting elements LE may be exposed without being covered by the fourth organic layer 192. The fourth organic layer 192 may be formed of an organic layer, such as acryl resin, epoxy resin, phenolic resin, polyamide resin, polyimide resin, or the like.

The third organic layer 191 and the fourth organic layer 192 are layers for flattening, or planarizing, the stepped portion caused by the plurality of light-emitting elements LE. When the third organic layer 191 has a height to cover most of the side surfaces of the plurality of light-emitting elements LE, the fourth organic layer 192 may be omitted.

The common electrode CE may be located on the top surface of each of the plurality of light-emitting elements LE and the top surface of the fourth organic layer 192. The common electrode CE may be a common layer commonly formed for the first sub-pixel SPX1, the second sub-pixel SPX2, and the third sub-pixel SPX3. The common electrode CE may be made of a transparent conductive material (TCO), such as indium tin oxide (ITO) and indium zinc oxide (IZO) capable of transmitting light.

Meanwhile, the pixel electrode PXE may be referred to as an anode electrode or a first electrode, and the common electrode CE may be referred to as a cathode electrode or a second electrode.

A first capping layer CAP1 may be located on the common electrode CE. The first capping layer CAP1 may be formed of an inorganic layer, for example, a silicon nitride layer, a silicon oxynitride layer, a silicon oxide layer, a titanium oxide layer, or an aluminum oxide layer.

A light-blocking layer BM, the first light conversion layer QDL1, the second light conversion layer QDL2, and the light-transmitting layer TPL may be located on the first capping layer CAP1. However, the present disclosure is not limited thereto, and a third light conversion layer may be located instead of the light-transmitting layer TPL. In this case, the third light conversion layer may include a material different from those of the first light conversion layer QDL1 and the second light conversion layer QDL2. For example, the first light conversion layer QDL1 may include quantum dots that convert light in the blue wavelength band into light in the red wavelength band, the second light conversion layer QDL2 may include quantum dots that convert light in the blue wavelength band into light in the green wavelength band, and the third light conversion layer may include blue phosphors. Further, each of the first light conversion layer QDL1, the second light conversion layer QDL2, and the third light conversion layer may include a light-dispersing agent, such as titanium dioxide (TiO₂) as well as quantum dots. In this case, the number of titanium dioxide (TiO₂) particles in the third light conversion layer may be larger than the number of titanium dioxide (TiO₂) particles in the first light conversion layer QDL1 or the number of titanium dioxide (TiO₂) particles in the second light conversion layer QDL2.

The first light conversion layer QDL1, the second light conversion layer QDL2, and the light-transmitting layer TPL may be formed by partitioning the light-blocking layer BM. Therefore, the first light conversion layer QDL1 may be located on the first capping layer CAP1 in the first sub-pixel SPX1, the second light conversion layer QDL2 may be located on the first capping layer CAP1 in the second sub-pixel SPX2, and the light-transmitting layer TPL may be located on the first capping layer CAP1 in the third sub-pixel SPX3. The light-blocking layer BM may overlap the bank 190 in the third direction DR3, and may not overlap the plurality of light-emitting elements LE.

The first light conversion layer QDL1 may convert a portion of the third light (light in the blue wavelength band) incident from the light-emitting element LE into the first light (light in the red wavelength band). The first light conversion layer QDL1 may include a first base resin BRS1 and a first wavelength conversion particle WCP1. The first base resin BRS1 may include a light-transmissive organic material. For example, the first base resin BRS1 may contain epoxy resin, acrylic resin, cardo resin, or imide resin. The first wavelength conversion particle WCP1 may convert a portion of the third light (light in the blue wavelength band) incident from the light-emitting element LE into the first light (light in the red wavelength band). The first wavelength conversion particle WCP1 may be a quantum dot (QD), a quantum rod, a fluorescent material, or a phosphorescent material. The first light conversion layer QDL1 may further include a light-dispersing agent, such as titanium dioxide (TiO₂).

The second light conversion layer QDL2 may convert a portion of the third light (light in the blue wavelength band) incident from the light-emitting element LE into the second light (light in the green wavelength band). The second light conversion layer QDL2 may include a second base resin BRS2 and second wavelength conversion particles WCP2. The second base resin BRS2 may contain a light-transmissive organic material. For example, the second base resin BRS2 may contain epoxy resin, acrylic resin, cardo resin, or imide resin. The second wavelength conversion particle WCP2 may convert a portion of the third light (light in the blue wavelength band) incident from the light-emitting element LE into the second light (light in the green wavelength band). The second wavelength conversion particle WCP2 may be a quantum dot (QD), a quantum rod, a fluorescent material, or a phosphorescent material. The second light conversion layer QDL2 may further include a light-dispersing agent, such as titanium dioxide (TiO₂).

The light-transmitting layer TPL may include a light-transmissive organic material. For example, the light-transmitting layer TPL may include epoxy resin, acrylic resin, cardo resin, imide resin, or the like.

The light-blocking layer BM may include a first light-blocking layer BM1 and a second light-blocking layer BM2 that are sequentially stacked. The length of the first light-blocking layer BM1 in the first direction DR1 or the length of the first light-blocking layer BM1 in the second direction DR2 may be longer than the length of the second light-blocking layer BM2 in the first direction DR1 or the length of the second light-blocking layer BM2 in the second direction DR2. The length (e.g., thickness or height) of the first light-blocking layer BM1 in the third direction DR3 may be greater than the length (e.g., thickness or height) of the second light-blocking layer BM2 in the third direction DR3. The first light-blocking layer BM1 and the second light-blocking layer BM2 may be formed of an organic layer, such as acryl resin, epoxy resin, phenolic resin, polyamide resin, polyimide resin and the like. For example, the first light-blocking layer BM1 and the second light-blocking layer BM2 may contain an organic block pigment or an inorganic black pigment, such as carbon black or the like.

The second capping layer CAP2 may be located on the first capping layer CAP1 and the light-blocking layer BM. The second capping layer CAP2 may be located on the side and top surfaces of the light-blocking layer BM. That is, the second capping layer CAP2 may be located on the side surface of the first light-blocking layer BM1, and the side and top surfaces of the second light-blocking layer BM2. The second capping layer CAP2 serves to protect the first wavelength conversion particles WCP1 of the first light conversion layer QDL1 and the second wavelength conversion particles WCP2 of the second light conversion layer QDL2 from moisture permeation, and thus may surround the upper portion, the lower portion, and the side surface(s) of the first light conversion layer QDL1 and the second light conversion layer QDL2.

A reflection layer RF may be located between the light-blocking layer BM and the first light conversion layer QDL1, between the light-blocking layer BM and the second light conversion layer QDL2, and between the light-blocking layer BM and the light-transmitting layer TPL. The reflection layer RF may be located on the second capping layer CAP2 located on the side surface of the first light-blocking layer BM1 and the side surface of the second light-blocking layer BM2. The reflection layer RF serves to reflect light traveling in the lateral direction from the first light conversion layer QDL1, the second light conversion layer QDL2, and the light-transmitting layer TPL.

The reflection layer RF may include a metal material having high reflectivity, such as aluminum (Al). The thickness of the reflection layer RF may be about 0.1 μm.

Alternatively, the reflection layer RF may include M (M being an integer of 2 or more) pairs of first layers and second layers having different refractive indices to serve as a distributed Bragg reflector (DBR). In this case, M first layers and M second layers may be alternately arranged. The first layer and the second layer may be formed of an inorganic layer, for example, a silicon nitride layer, a silicon oxynitride layer, a silicon oxide layer, a titanium oxide layer, or an aluminum oxide layer.

The third capping layer CAP3 may be located on the second capping layer CAP2, the first light conversion layer QDL1, the second light conversion layer QDL2, and the light-transmitting layer TPL. The third capping layer CAP3 may be formed of an inorganic layer, for example, a silicon nitride layer, a silicon oxynitride layer, a silicon oxide layer, a titanium oxide layer, or an aluminum oxide layer. The first light conversion layer QDL1, the second light conversion layer QDL2, and the light-transmitting layer TPL may be encapsulated by the first capping layer CAP1, the second capping layer CAP2, and the third capping layer CAP3. The refractive index of the third capping layer CAP3 may be lower than the refractive index of the second capping layer CAP2. Further, the refractive index of the third capping layer CAP3 may be lower than the refractive index of a fifth organic layer 193.

The fifth organic layer 193 may be located on the second capping layer CAP2. The fifth organic layer 193 may be formed of acryl resin, epoxy resin, phenolic resin, polyamide resin, polyimide resin or the like.

A plurality of color filters CF1, CF2, and CF3 may be located on the fifth organic layer 193. The plurality of color filters CF1, CF2 and CF3 may include first color filters CF1, second color filters CF2, and third color filters CF3. However, the present disclosure is not limited thereto, and if the light-emitting elements LE of the first sub-pixel SPX1 emit light of the first color, if the light-emitting elements LE of the second sub-pixel SPX2 emit light of the second color, and if the light-emitting elements LE of the third sub-pixel SPX3 emit light of the third color, the first light conversion layer QDL1, the second light conversion layer QDL2, the light-transmitting layer TPL, and the light-blocking layer BM may be omitted, the fifth organic layer 193 may be located on the common electrode CE, and the plurality of color filters CF1, CF2, and CF3 may be located on the fifth organic layer 193, or the plurality of color filters CF1, CF2, and CF3 may be omitted.

The first color filter CF1 located in the first sub-pixel SPX1 may transmit the first light (light in the red wavelength band), and may absorb or block the third light (light in the blue wavelength band). Therefore, the first color filter CF1 may transmit the first light (light in the red wavelength band) converted by the first light conversion layer QDL1 among the third light (light in the blue wavelength band) emitted from the light-emitting element LE, and may absorb or block the third light (light in the blue wavelength band) that is not converted by the first light conversion layer QDL1. Accordingly, the first sub-pixel SPX1 may emit the first light (light in the red wavelength band).

The second color filter CF2 located in the second sub-pixel SPX2 may transmit the second light (light in the green wavelength band), and may absorb or block the third light (light in the blue wavelength band). Therefore, the second color filter CF2 may transmit the second light (light in the green wavelength band) converted by the second light conversion layer QDL2 among the third light (light in the blue wavelength band) emitted from the light-emitting element LE, and may absorb or block the third light (light in the blue wavelength band) that is not converted by the second light conversion layer QDL2. Accordingly, the second sub-pixel SPX2 may emit the second light (light in the green wavelength band).

The third color filter CF3 located in the third sub-pixel SPX3 may transmit the third light (light in the blue wavelength band). Therefore, the third color filter CF3 may transmit the third light (light in the blue wavelength band) emitted from the light-emitting element LE and passing through the light-transmitting layer TPL. Accordingly, the third sub-pixel SPX3 may emit the third light (light in the blue wavelength band).

Each of the first to third color filters CF1, CF2, and CF3 serves to block external light incident from the outside. For example, the first color filter CF1 located in the first sub-pixel SPX1 blocks the second light that is the light in the green wavelength band and the third light that is the light in the blue wavelength band, which are incident from the outside, so that the purity (color purity) of the color corresponding to the first light that is the light in the red wavelength band may be increased.

The first color filter CF1, the second color filter CF2, and the third color filter CF3 overlapping in the third direction DR3 may overlap the bank 190 and the light-blocking layer BM in the third direction DR3.

A sixth organic layer 194 for planarization may be located on the plurality of color filters CF1, CF2, and CF3. The sixth organic layer 194 may be formed of acryl resin, epoxy resin, phenolic resin, polyamide resin, polyimide resin or the like.

Referring to FIGS. 7 and 8, the organic layer 210 is located on the first pixel electrode PXE1, the second pixel electrode PXE2, and the third pixel electrode PXE3, and the contact electrode CTE of the light-emitting element LE is connected to the first pixel electrode PXE1, the second pixel electrode PXE2, or the third pixel electrode PXE3 using the connection electrode BE. Therefore, the organic layer 210 may reduce or prevent the likelihood of the plurality of light-emitting elements LE tilting or falling during the process of transferring the plurality of light-emitting elements LE to the display panel 100. Further, despite the organic layer 210, the contact electrode CTE of the light-emitting element LE may be electrically connected to the first pixel electrode PXE1, the second pixel electrode PXE2, or the third pixel electrode PXE3.

Further, the contact electrode CTE is located on the passivation layer INS located on the side surface of the first semiconductor layer SEM1, so that the contact area between the contact electrode CTE and the connection electrode BE may increase. Therefore, the contact resistance between the contact electrode CTE and the connection electrode BE may be reduced, and the contact electrode CTE and the connection electrode BE may be more stably connected.

Further, the side surface of the contact electrode CTE and the side surface of the organic layer 210 are aligned, so that a stepped portion may not be formed at the interface between the contact electrode CTE and the organic layer 210.

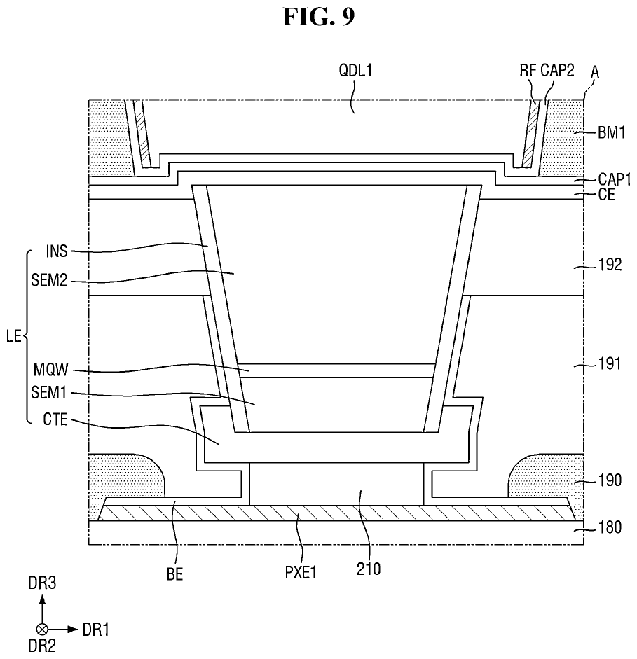

FIG. 9 is a cross-sectional view showing another example of area A of FIG. 7.

The one or more embodiments corresponding to FIG. 9 is different from the one or more embodiments corresponding to FIG. 8 in that the side surface of the contact electrode CTE protrudes more than the side surface of the organic layer 210, and in the one or more embodiments corresponding to FIG. 9, redundant description of the parts already described in the one or more embodiments corresponding to FIG. 8 will be omitted.

Referring to FIG. 9, the side surface of the contact electrode CTE protrudes (e.g., outwardly) more than the side surface of the organic layer 210, so that a portion of the bottom surface of the contact electrode CTE may be exposed. Thus, the connection electrode BE may be located on the side surface of the organic layer 210, and the side surface and a portion of the bottom surface of the contact electrode CTE.

In accordance with the one or more embodiments corresponding to FIG. 9, the connection electrode BE is also in contact with a portion of the bottom surface of the contact electrode CTE, the contact area between the contact electrode CTE and the connection electrode BE may increase. Therefore, the contact resistance between the contact electrode CTE and the connection electrode BE may be reduced, and the contact electrode CTE and the connection electrode BE may be more stably connected.

The width of the organic layer 210 may be the same as the width of the bottom surface of the light-emitting element LE, but the present disclosure is not limited thereto. For example, the width of the organic layer 210 may be less than the width of the bottom surface of the light-emitting element LE. In contrast, the width of the contact electrode CTE may be greater than the width of the bottom surface of the light-emitting element LE. Meanwhile, the width of the organic layer 210 may be defined as the length in the first direction DR1 or the length in the second direction DR2 of the organic layer 210. The width of the bottom surface of the light-emitting element LE may be defined as the length in the first direction DR1 or the length in the second direction DR2 of the bottom surface of the light-emitting element LE. The width of the contact electrode CTE may be defined as the length in the first direction DR1 or the length in the second direction DR2 of the contact electrode CTE.

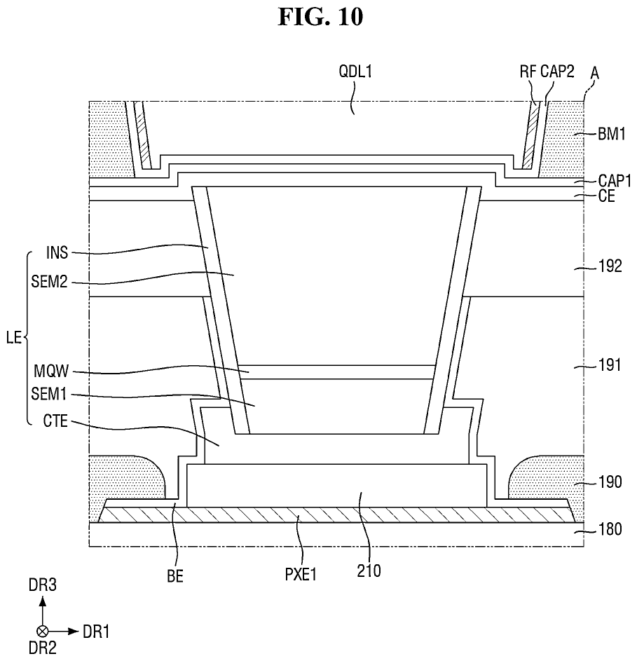

FIG. 10 is a cross-sectional view showing still another example of area A of FIG. 7.

The one or more embodiments corresponding to FIG. 10 is different from the one or more embodiments corresponding to FIG. 8 in that the side surface of the organic layer 210 protrudes more than the side surface of the contact electrode CTE, and in the one or more embodiments corresponding to FIG. 10, redundant description of the parts already described in the one or more embodiments corresponding to FIG. 8 will be omitted.

Referring to FIG. 10, the side surface of the organic layer 210 protrudes more than the side surface of the contact electrode CTE, so that a portion of the top surface of the organic layer 210 may be exposed without being covered by the contact electrode CTE. Thus, the connection electrode BE may be located on the side surface and a portion of the top surface of the organic layer 210, and the side surface of the contact electrode CTE. Further, the width of the contact electrode CTE may be greater than the width of the bottom surface of the light-emitting element LE, and the width of the organic layer 210 may be greater than the width of the contact electrode CTE.

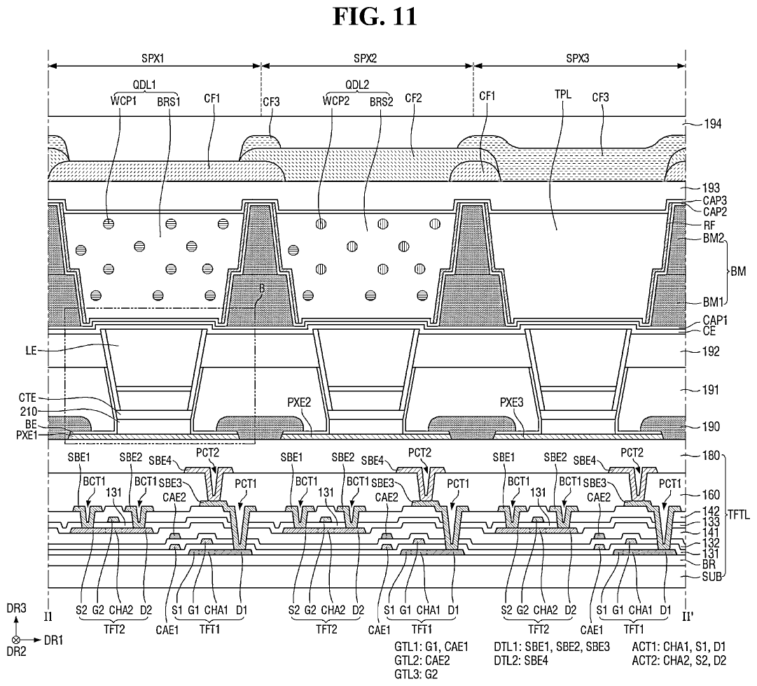

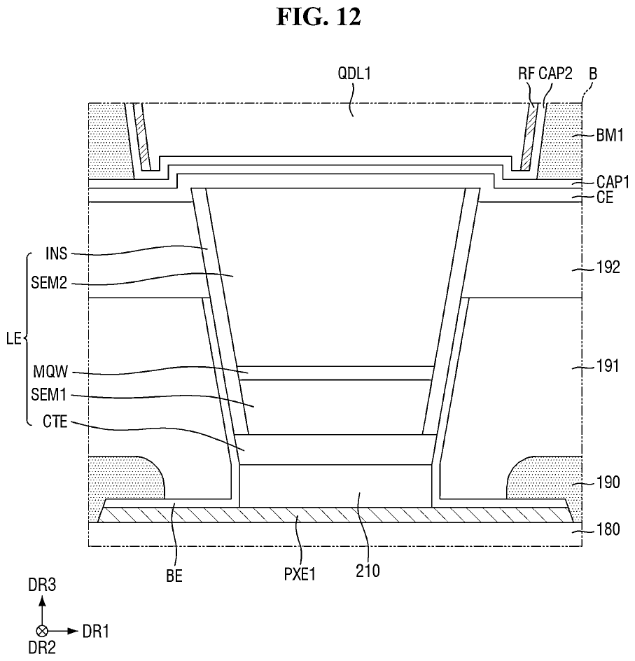

FIG. 11 is a cross-sectional view showing the display panel taken along the line I1-I1′ of FIG. 6. FIG. 12 is a plan view illustrating an example of area B of FIG. 11.

The one or more embodiments corresponding to FIGS. 11 and 12 is different from the one or more embodiments corresponding to FIGS. 7 and 8 in that the contact electrode CTE is not located on the passivation layer INS located on the side surface of the first semiconductor layer SEM1. In the embodiments of FIGS. 11 and 12, redundant description of the parts already described in the one or more embodiments corresponding to FIGS. 7 and 8 will be omitted.

In accordance with the one or more embodiments corresponding to FIGS. 11 and 12, the side surface of the contact electrode CTE may be aligned with the side surface of the organic layer 210. Accordingly, the side surface of the contact electrode CTE, the side surface of the organic layer 210, and one surface (e.g., the outer surface) of the passivation layer INS may be connected to be flat. Therefore, it is possible to reduce or prevent the likelihood of the connection electrode BE being disconnected on the side surface of the contact electrode CTE, the side surface of the organic layer 210, and one surface (e.g., the outer surface) of the passivation layer INS.

Further, the side surface of the contact electrode CTE and the side surface of the organic layer 210 are aligned, so that a stepped portion may not be formed at the interface between the contact electrode CTE and the organic layer 210.

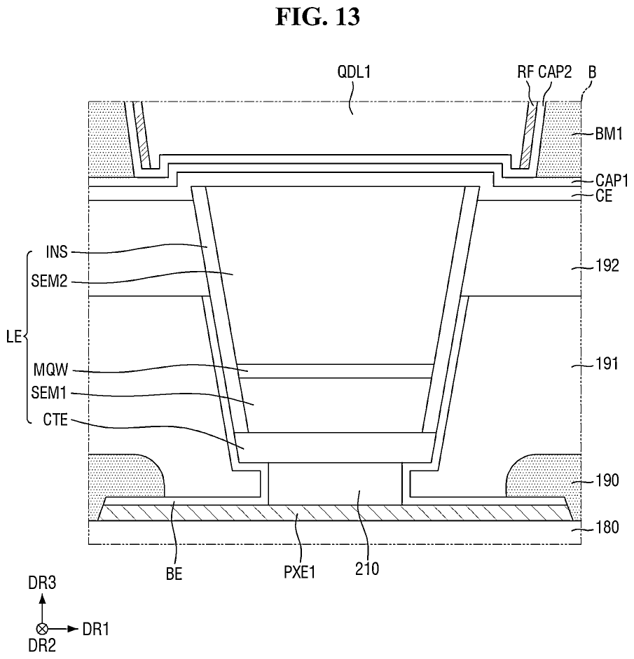

FIG. 13 is a cross-sectional view showing another example of area B of FIG. 11.

The one or more embodiments corresponding to FIG. 13 is different from the one or more embodiments corresponding to FIG. 12 in that the side surface of the contact electrode CTE protrudes more than the side surface of the organic layer 210, and in the one or more embodiments corresponding to FIG. 13, redundant description of the parts already described in the one or more embodiments corresponding to FIG. 12 will be omitted.

Referring to FIG. 13, the side surface of the contact electrode CTE protrudes more than the side surface of the organic layer 210, so that a portion of the bottom surface of the contact electrode CTE may be exposed. Thus, the connection electrode BE may be located on the side surface of the organic layer 210, and the side surface and a portion of the bottom surface of the contact electrode CTE.

The width of the organic layer 210 may be less than the width of the bottom surface of the light-emitting element LE, but the present disclosure is not limited thereto. For example, the width of the organic layer 210 may be the same as the width of the bottom surface of the light-emitting element LE. In contrast, the width of the contact electrode CTE may be greater than the width of the bottom surface of the light-emitting element LE.

In accordance with the one or more embodiments corresponding to FIG. 13, the connection electrode BE is also in contact with a portion of the bottom surface of the contact electrode CTE, so that the contact area between the contact electrode CTE and the connection electrode BE may increase. Therefore, the contact resistance between the contact electrode CTE and the connection electrode BE may be reduced, and the contact electrode CTE and the connection electrode BE may be more stably connected. Further, the width of the contact electrode CTE may be greater than the width of the bottom surface of the light-emitting element LE, and the width of the organic layer 210 may be greater than the width of the contact electrode CTE.

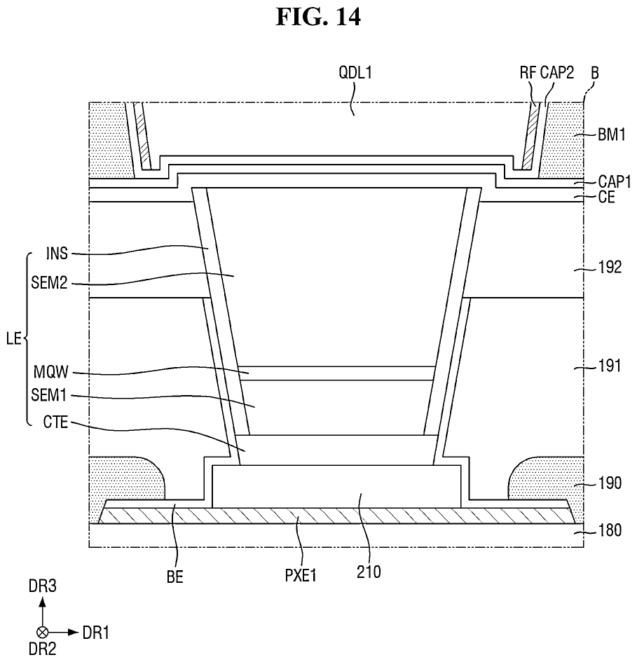

FIG. 14 is a cross-sectional view showing still another example of area B of FIG. 11.

The one or more embodiments corresponding to FIG. 14 is different from the one or more embodiments corresponding to FIG. 12 in that the side surface of the organic layer 210 protrudes more than the side surface of the contact electrode CTE, and in the one or more embodiments corresponding to FIG. 14, redundant description of the parts already described in the one or more embodiments corresponding to FIG. 12 will be omitted.

Referring to FIG. 14, the side surface of the organic layer 210 protrudes more than the side surface of the contact electrode CTE, so that a portion of the top surface of the organic layer 210 may be exposed without being covered by the contact electrode CTE. Thus, the connection electrode BE may be located on the side surface and a portion of the top surface of the organic layer 210, and the side surface of the contact electrode CTE.

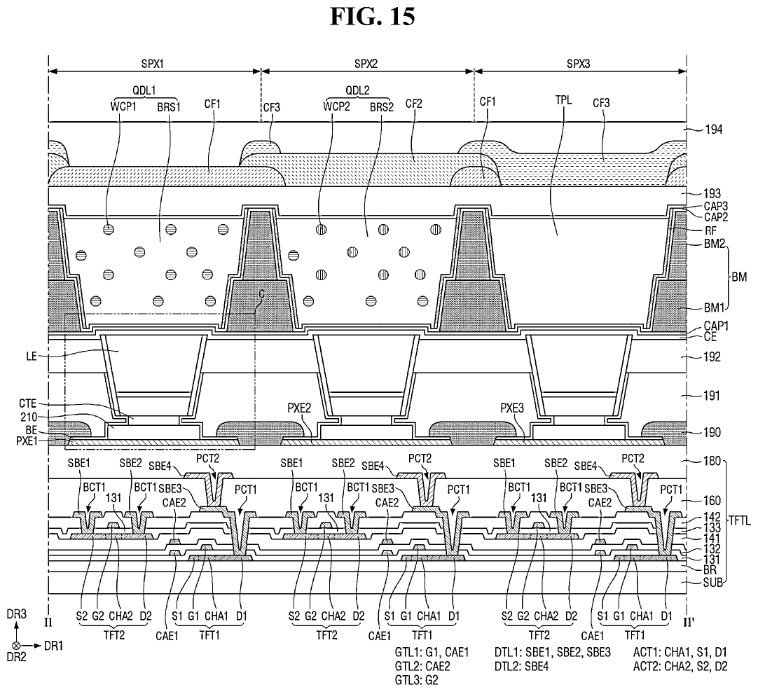

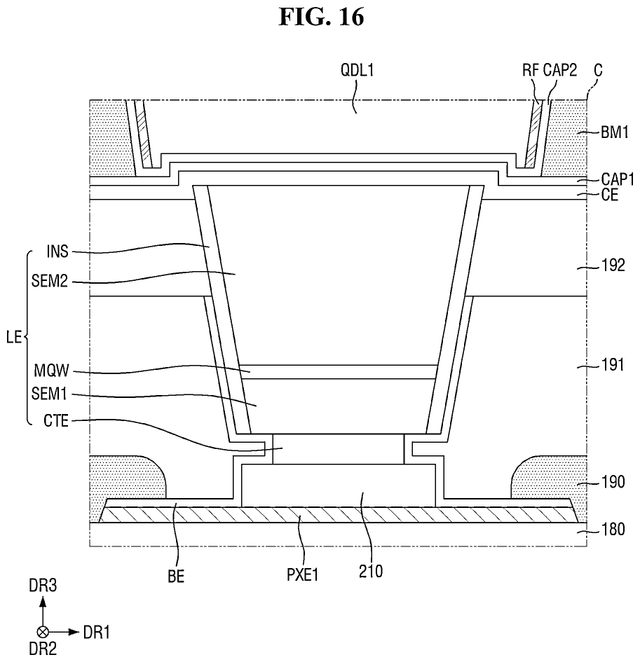

FIG. 15 is a cross-sectional view showing the display panel taken along the line I1-I1′ of FIG. 6. FIG. 16 is a cross-sectional view illustrating an example of area C of FIG. 15.

The one or more embodiments corresponding to FIGS. 15 and 16 is different from the one or more embodiments corresponding to FIGS. 7 and 8 in that the contact electrode CTE is located on a portion of the bottom surface of the first semiconductor layer SEM1. In the embodiments of FIGS. 15 and 16, redundant description of the parts already described in the one or more embodiments corresponding to FIGS. 7 and 8 will be omitted.

In accordance with the one or more embodiments corresponding to FIGS. 15 and 16, the contact electrode CTE is located on a portion of the bottom surface of the first semiconductor layer SEM1, so that the length in the first direction DR1 (or the length in the second direction DR2) of the contact electrode CTE is less than the length in the first direction DR1 (or the length in the second direction DR2) of the bottom surface of the first semiconductor layer SEM1. The contact electrode CTE is not located on the passivation layer INS located on the side surface of the first semiconductor layer SEM1.

The edge of the top surface of the organic layer 210 may be exposed without being covered by the contact electrode CTE, so that the connection electrode BE may be located on the edge of the top surface of the organic layer 210. Further, the connection electrode BE may be located on at least a portion of the bottom surface of the first semiconductor layer SEM1 and the bottom surface of the passivation layer INS.

Further, the width of the organic layer 210 may be greater than the width of the contact electrode CTE. The width of the bottom surface of the light-emitting element LE may be greater than the width of the contact electrode CTE.

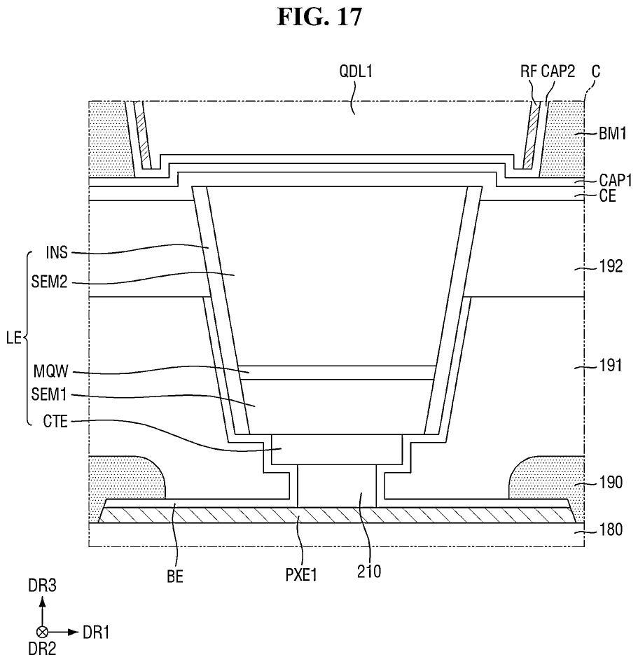

FIG. 17 is a cross-sectional view showing another example of area C of FIG. 15.

The one or more embodiments corresponding to FIG. 17 is different from the one or more embodiments corresponding to FIG. 16 in that the side surface of the contact electrode CTE protrudes more than the side surface of the organic layer 210, and in the one or more embodiments corresponding to FIG. 17, redundant description of the parts already described in the one or more embodiments corresponding to FIG. 16 will be omitted.

Referring to FIG. 17, the side surface of the contact electrode CTE protrudes more than the side surface of the organic layer 210, so that a portion of the bottom surface of the contact electrode CTE may be exposed. Thus, the connection electrode BE may be located on the side surface of the organic layer 210, and the side surface and a portion of the bottom surface of the contact electrode CTE.

In accordance with the one or more embodiments corresponding to FIG. 17, the connection electrode BE is also in contact with a portion of the bottom surface of the contact electrode CTE, so that the contact area between the contact electrode CTE and the connection electrode BE may increase. Therefore, the contact resistance between the contact electrode CTE and the connection electrode BE may be reduced, and the contact electrode CTE and the connection electrode BE may be more stably connected.

Further, the width of the organic layer 210 may be less than the width of the contact electrode CTE. The width of the bottom surface of the light-emitting element LE may be greater than the width of the contact electrode CTE.

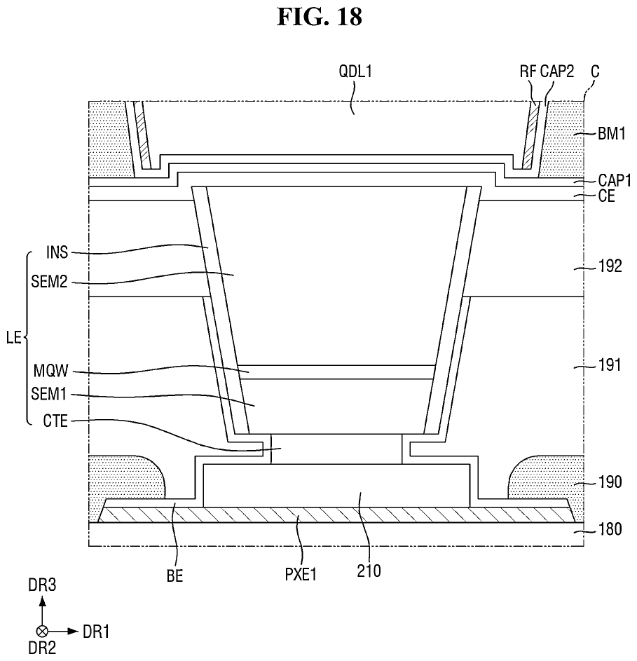

FIG. 18 is a cross-sectional view showing still another example of area C of FIG. 15.

The one or more embodiments corresponding to FIG. 18 is different from the one or more embodiments corresponding to FIG. 16 in that the side surface of the organic layer 210 protrudes more than the side surface of the contact electrode CTE, and in the one or more embodiments corresponding to FIG. 18, redundant description of the parts already described in the one or more embodiments corresponding to FIG. 16 will be omitted.

Referring to FIG. 18, the side surface of the organic layer 210 protrudes more than the side surface of the contact electrode CTE, so that a portion of the top surface of the organic layer 210 may be exposed without being covered by the contact electrode CTE. Thus, the connection electrode BE may be located on the side surface and a portion of the top surface of the organic layer 210, and the side surface of the contact electrode CTE.

Further, the width of the organic layer 210 may be greater than the width of the contact electrode CTE. The width of the bottom surface of the light-emitting element LE may be greater than the width of the contact electrode CTE. The width of the organic layer 210 may be greater than the width of the bottom surface of the light-emitting element LE.

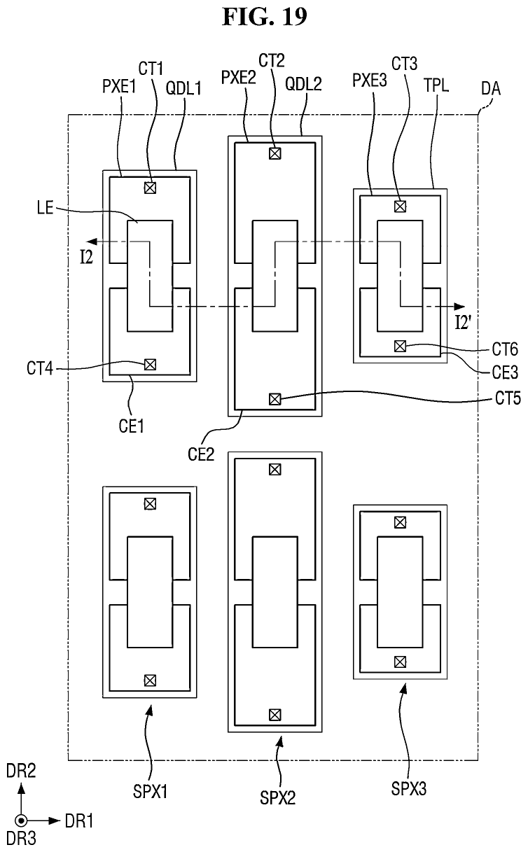

FIG. 19 is a layout view illustrating pixels of a display area according to one or more embodiments.

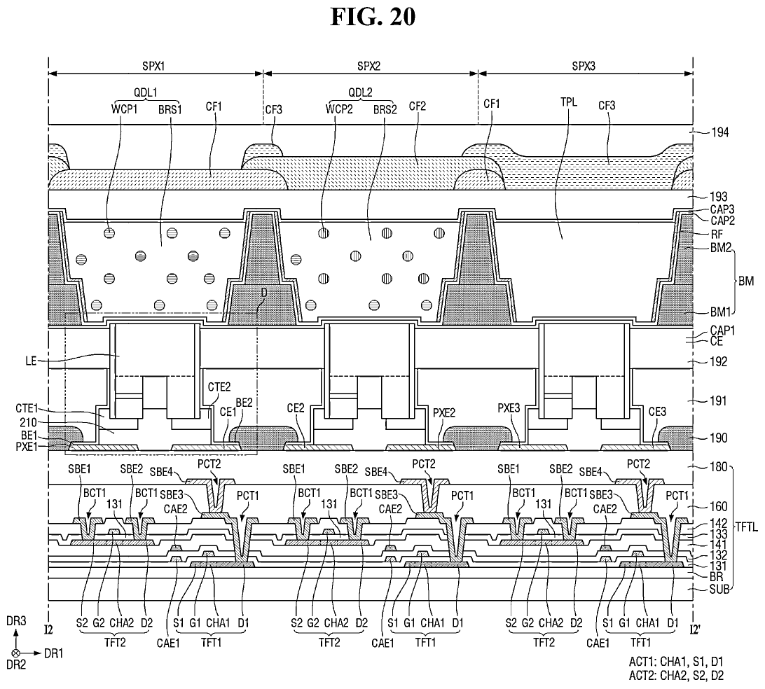

The one or more embodiments corresponding to FIG. 19 is different from the one or more embodiments corresponding to FIG. 6 in that the first sub-pixel SPX1 further includes a first common electrode CE1 (e.g., see FIG. 20), the second sub-pixel SPX2 further includes a second common electrode CE2 (e.g., see FIG. 20), and the third sub-pixel SPX3 further includes a third common electrode CE3 (e.g., see FIG. 20). In the one or more embodiments corresponding to FIG. 19, redundant description of parts already described in the one or more embodiments corresponding to FIG. 6 will be omitted.

Referring to FIG. 19, each of the first pixel electrode PXE1, the second pixel electrode PXE2, the third pixel electrode PXE3, the first common electrode CE1, the second common electrode CE2, and the third common electrode CE3 may have a rectangular planar shape. The area of the first sub-pixel SPX1, the area of the second sub-pixel SPX2, and the area of the third sub-pixel SPX3 may be set depending on the light conversion efficiency of the first light conversion layer QDL1 and the light conversion efficiency of the second light conversion layer QDL2.

For example, as shown in FIG. 19, the area of the second pixel electrode PXE2 may be greater than the area of the first pixel electrode PXE1, and the area of the first pixel electrode PXE1 may be greater than the area of the third pixel electrode PXE3. Further, the area of the second common electrode CE2 may be greater than the area of the first common electrode CE1, and the area of the first common electrode CE1 may be greater than the area of the third common electrode CE3.

The area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3, but the present disclosure is not limited thereto.

In the first sub-pixel SPX1, the first pixel electrode PXE1 and the first common electrode CE1 may be arranged to be spaced apart from each other in the second direction DR2. In the second sub-pixel SPX2, the second pixel electrode PXE2 and the second common electrode CE2 may be arranged to be spaced apart from each other in the second direction DR2. In the third sub-pixel SPX3, the third pixel electrode PXE3 and the third common electrode CE3 may be arranged to be spaced apart from each other in the second direction DR2.

The first pixel electrode PXE1 may be electrically connected to the second electrode of the fourth transistor ST4 (see FIGS. 4 and 5) of the first sub-pixel SPX1 and to the second electrode of the sixth transistor ST6 (see FIGS. 4 and 5) thereof through the first connection hole CT1. The second pixel electrode PXE2 may be electrically connected to the second electrode of the fourth transistor ST4 (see FIGS. 4 and 5) of the second sub-pixel SPX2 and to the second electrode of the sixth transistor ST6 (see FIGS. 4 and 5) thereof through the second connection hole CT2. The third pixel electrode PXE3 may be electrically connected to the second electrode of the fourth transistor ST4 (see FIGS. 4 and 5) of the third sub-pixel SPX3 and to the second electrode of the sixth transistor ST6 (see FIGS. 4 and 5) thereof through the third connection hole CT3.

The first common electrode CE1 may be connected to the second power line VSL to which the second driving voltage VSS is applied through a fourth connection hole CT4. The second common electrode CE2 may be connected to the second power line VSL through a fifth connection hole CT5. The third common electrode CE3 may be connected to the second power line VSL through a sixth connection hole CT6. Therefore, the second driving voltage VSS may be applied to the first common electrode CE1, the second common electrode CE2, and the third common electrode CE3.

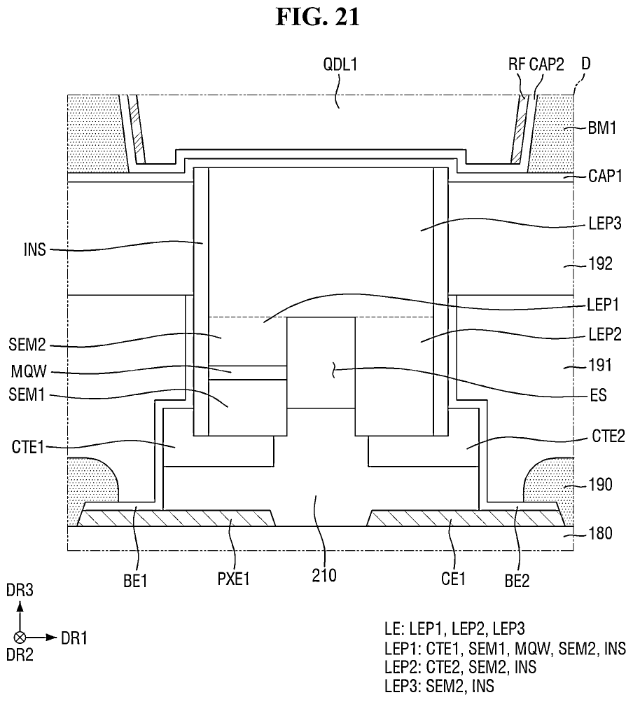

FIG. 20 is a cross-sectional view showing the display panel taken along the line I2-I2′ of FIG. 19. FIG. 21 is a cross-sectional view illustrating an example of area D of FIG. 20.

The one or more embodiments corresponding to FIGS. 20 and 21 is different from the one or more embodiments corresponding to FIGS. 7 and 8 in that the light-emitting element LE is a flip type micro LED. In the embodiments of FIGS. 20 and 21, redundant description of the parts already described in the one or more embodiments corresponding to FIGS. 7 and 8 will be omitted.

Referring to FIGS. 20 and 21, the light-emitting element LE may be a flip type micro LED. The flip type micro LED refers to an LED in which contact electrodes CTE1 and CTE2 are formed on one surface (e.g., the bottom surface) of the light-emitting element LE.

The pixel electrode layer PXL including the pixel electrodes PXE1, PXE2, and PXE3 and the common electrodes CE1, CE2, and CE3 may be located on the second organic layer 180. The bank 190 may not be located on at least one edge of each of the pixel electrodes PXE1, PXE2, and PXE3 and at least one edge of each of the common electrodes CE1, CE2, and CE3.

For example, the bank 190 may not be located on one edge of the first pixel electrode PXE1 and one edge of the first common electrode CE1 that face each other. The bank 190 may be located on the other edges of the first pixel electrode PXE1 excluding the one edge, and on the other edges of the first common electrode CE1 excluding the one edge.

Further, the bank 190 may not be located on one edge of the second pixel electrode PXE2 and one edge of the second common electrode CE2 that face each other. The bank 190 may be located on the other edges of the second pixel electrode PXE2 excluding the one edge, and on the other edges of the second common electrode CE2 excluding the one edge.

Furthermore, the bank 190 may not be located on one edge of the third pixel electrode PXE3 and one edge of the third common electrode CE3 that face each other. The bank 190 may be located on the other edges of the third pixel electrode PXE3 excluding the one edge, and on the other edges of the third common electrode CE3 excluding the one edge.

The light-emitting element LE includes first to third portions LEP1, LEP2, and LEP3. The first portion LEP1 and the second portion LEP2 may be spaced apart from each other. The third portion LEP3 may be connected to the first portion LEP1 and to the second portion LEP2. The third portion LEP3 may be located on the first portion LEP1 and on the second portion LEP2.

The first portion LEP1 includes the first contact electrode CTE1, the first semiconductor layer SEM1, the active layer MQW, the second semiconductor layer SEM2, and the passivation layer INS. The second portion LEP2 includes the second contact electrode CTE2, the second semiconductor layer SEM2, and the passivation layer INS, and the third portion LEP3 includes the second semiconductor layer SEM2 and the passivation layer INS.

The first semiconductor layer SEM1 may be located on the first contact electrode CTE1, the active layer MQW may be located on the first semiconductor layer SEM1, and the second semiconductor layer SEM2 may be located on the active layer MQW.

The third semiconductor layer SEM3 of the third portion LEP3 may be connected to the second semiconductor layer SEM2 of the first portion LEP1 and the second semiconductor layer SEM2 of the second portion LEP2. The second semiconductor layer SEM2 of the first portion LEP1, the second semiconductor layer SEM2 of the second portion LEP2, and the third semiconductor layer SEM3 of the third portion LEP3 may be formed integrally.

The first contact electrode CTE1 may be located on at least a portion of the outer surface and the bottom surface of the first semiconductor layer SEM1. The second contact electrode CTE2 may be located on at least a portion of the outer surface and the bottom surface of the second semiconductor layer SEM2 of the second portion LEP2. The first contact electrode CTE1 and the second contact electrode CTE2 may include any one of molybdenum (Mo), aluminum (Al), chromium (Cr), gold (Au), titanium (Ti), nickel (Ni), neodymium (Nd), or copper (Cu).

The passivation layer INS may be located on the outer surface of the first portion LEP1, the outer surface of the second portion LEP2, and the side surface of the third portion LEP3. For example, the passivation layer INS may be located on the outer surface of the first semiconductor layer SEM1, the outer surface of the active layer MQW, and the outer surface of the second semiconductor layer SEM2 in the first portion LEP1. Further, the passivation layer INS may be located on the outer surface of the second semiconductor layer SEM2 in the second portion LEP2. Furthermore, the passivation layer INS may be located on the side surface of the second semiconductor layer SEM2 in the third portion LEP3.

The organic layer 210 may be located on the bottom surface of the first contact electrode CTE1 and on the bottom surface of the second contact electrode CTE2, and may be located between the first contact electrode CTE1 and the second contact electrode CTE2. Further, the organic layer 210 may be located between the first semiconductor layer SEM1 of the first portion LEP1 and the second semiconductor layer SEM2 of the second portion LEP2.

Although FIG. 20 illustrates that an empty space ES is located between the active layer MQW of the first portion LEP1 and the second semiconductor layer SEM2 of the second portion LEP2, and between the second semiconductor layer SEM2 of the first portion LEP1 and the second semiconductor layer SEM2 of the second portion LEP2, the organic layer 210 may be located between the active layer MQW of the first portion LEP1 and the second semiconductor layers SEM2 of the second portion LEP2. Alternatively, the organic layer 210 may be located both between the active layer MQW of the first portion LEP1 and the second semiconductor layer SEM2 of the second portion LEP2, and between the second semiconductor layer SEM2 of the first portion LEP1 and the second semiconductor layer SEM2 of the second portion LEP2.

A first connection electrode BE1 connects the first contact electrode CTE1 to the first pixel electrode PXE1, the second pixel electrode PXE2, or the third pixel electrode PXE3. The first connection electrode BE1 may be located on the top surface of the first pixel electrode PXE1, the second pixel electrode PXE2, or the third pixel electrode PXE3 that is exposed without being covered by the organic layer 210. Further, the first connection electrode BE1 may be located on the side surface of the organic layer 210 and the side surface of the first contact electrode CTE1. Further, the first connection electrode BE1 may be located on the outer surface of the first portion LEP1 and a portion of the side surface of the third portion LEP3 of the light-emitting element LE. The first connection electrode BE1 may be located on a portion of the passivation layer INS of the light-emitting element LE.

A second connection electrode BE2 connects the second contact electrode CTE2 to a corresponding one of the first common electrode CE1, the second common electrode CE2, or the third common electrode CE3. The second connection electrode BE2 may be located on the top surface of a corresponding one of the first common electrode CE1, the second common electrode CE2, or the third common electrode CE3 that is exposed without being covered by the organic layer 210. Further, the second connection electrode BE2 may be located on the side surface of the organic layer 210 and on the side surface of the second contact electrode CTE2. Further, the second connection electrode BE2 may be located on the outer surface of the second portion LEP2 and on a portion of the side surface of the third portion LEP3 of the light-emitting element LE. The second connection electrode BE2 may be located on a portion of the passivation layer INS of the light-emitting element LE.

Each of the first connection electrode BE1 and the second connection electrode BE2 may include any one of molybdenum (Mo), aluminum (Al), chromium (Cr), gold (Au), titanium (Ti), nickel (Ni), neodymium (Nd), or copper (Cu). Alternatively, each of the first connection electrode BE1 and the second connection electrode BE2 may be made of a transparent conductive material (TCO), such as indium tin oxide (ITO) and indium zinc oxide (IZO) capable of transmitting light.

When each of the first connection electrode BE1 and the second connection electrode BE2 is made of a metal material having high reflectivity, such as aluminum (Al), the light traveling in the lateral direction of the light-emitting element LE among the light emitted from the active layer MQW of the light-emitting element LE may be reflected from the connection electrode BE and travel in the upward direction of the light-emitting element LE. Therefore, the loss of light from the light-emitting element LE may be reduced, which makes it possible to increase the light efficiency of the light-emitting element LE.

Referring to FIGS. 20 and 21, the organic layer 210 is located on the first pixel electrode PXE1, the second pixel electrode PXE2, the third pixel electrode PXE3, the first common electrode CE1, the second common electrode CE2, and the third common electrode CE3. Further, the first contact electrode CTE1 of the light-emitting element LE is connected to the first pixel electrode PXE1, the second pixel electrode PXE2, or the third pixel electrode PXE3 using the first connection electrode BE1. Further, the second contact electrode CTE2 of the light-emitting element LE is connected to the first common electrode CE1, the second common electrode CE2, or the third common electrode CE3 using the second connection electrode BE2. Therefore, the organic layer 210 may reduce or prevent the likelihood of the plurality of light-emitting elements LE tilting or falling during the process of transferring the plurality of light-emitting elements LE to the display panel 100. Further, despite the organic layer 210, the first contact electrode CTE1 of the light-emitting element LE may be electrically connected to the first pixel electrode PXE1, the second pixel electrode PXE2, or the third pixel electrode PXE3. Further, despite the organic layer 210, the second contact electrode CTE2 of the light-emitting element LE may be electrically connected to the first common electrode CE1, the second common electrode CE2, or the third common electrode CE3.

Further, the first contact electrode CTE1 is located on the passivation layer INS located on the outer surface of the first portion LEP1 of the light-emitting element LE. Therefore, the contact area between the first contact electrode CTE1 and the first connection electrode BE1 may increase. Accordingly, the contact resistance between the first contact electrode CTE1 and the first connection electrode BE1 may be reduced, and the first contact electrode CTE1 and the first connection electrode BE1 may be more stably connected.

Further, the second contact electrode CTE2 is located on the passivation layer INS located on the outer surface of the second portion LEP2 of the light-emitting element LE. Therefore, the contact area between the second contact electrode CTE2 and the second connection electrode BE2 may increase. Accordingly, the contact resistance between the second contact electrode CTE2 and the second connection electrode BE2 may be reduced, and the second contact electrode CTE2 and the second connection electrode BE2 may be more stably connected.

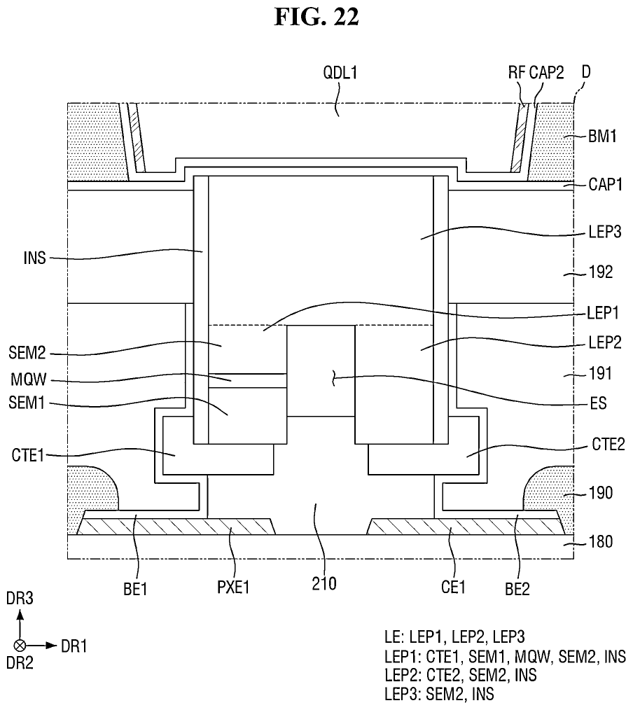

FIG. 22 is a cross-sectional view showing another example of area D of FIG. 20.

The one or more embodiments corresponding to FIG. 22 is different from the one or more embodiments corresponding to FIG. 21 in that the outer surface of the first contact electrode CTE1 protrudes more than the side surface of the organic layer 210, and the outer surface of the second contact electrode CTE2 protrudes more than the side surface of the organic layer 210, and in the one or more embodiments corresponding to FIG. 22, redundant description of the parts already described in the one or more embodiments corresponding to FIG. 21 will be omitted.

Referring to FIG. 22, the outer surface of the first contact electrode CTE1 protrudes more than the side surface of the organic layer 210, so that a portion of the bottom surface of the first contact electrode CTE1 may be exposed. Thus, the first connection electrode BE1 may be located on the side surface of the organic layer 210, and the outer surface and a portion of the bottom surface of the first contact electrode CTE1.

Further, the outer surface of the second contact electrode CTE2 protrudes more than the side surface of the organic layer 210, so that a portion of the bottom surface of the second contact electrode CTE2 may be exposed. Thus, the second connection electrode BE2 may be located on the side surface of the organic layer 210, and the outer surface and a portion of the bottom surface of the second contact electrode CTE2.

In accordance with the one or more embodiments corresponding to FIG. 22, the first connection electrode BE1 is also in contact with a portion of the bottom surface of the first contact electrode CTE1, so that the contact area between the first contact electrode CTE1 and the first connection electrode BE1 may increase. Accordingly, the contact resistance between the first contact electrode CTE1 and the first connection electrode BE1 may be reduced, and the first contact electrode CTE1 and the first connection electrode BE1 may be more stably connected.

Further, the second connection electrode BE2 is also in contact with a portion of the bottom surface of the second contact electrode CTE2, so that the contact area between the second contact electrode CTE2 and the second connection electrode BE2 may increase. Therefore, the contact resistance between the second contact electrode CTE2 and the second connection electrode BE2 may be reduced, and the second contact electrode CTE2 and the second connection electrode BE2 may be more stably connected.

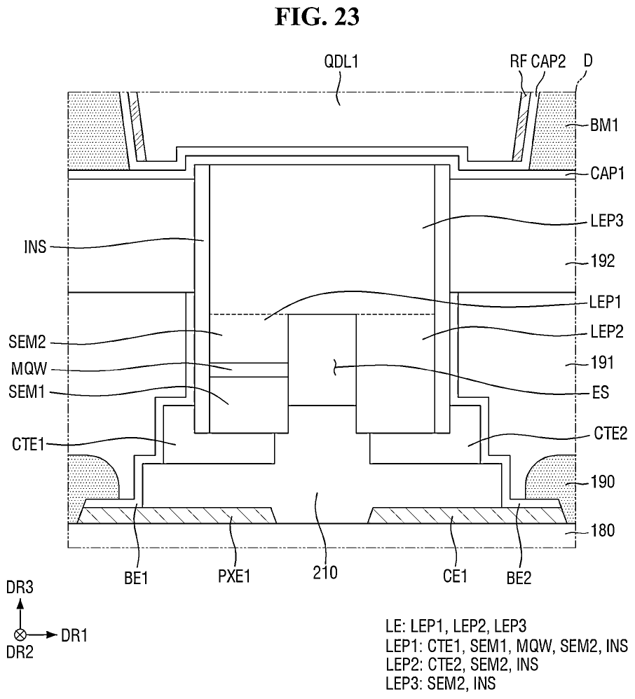

FIG. 23 is a cross-sectional view showing still another example of area D of FIG. 20.

The one or more embodiments corresponding to FIG. 23 is different from the one or more embodiments corresponding to FIG. 22 in that the side surface of the organic layer 210 protrudes more than the outer surface of the first contact electrode CTE1 and the outer surface of the second contact electrode CTE2, and in the one or more embodiments corresponding to FIG. 23, redundant description of the parts already described in the one or more embodiments corresponding to FIG. 22 will be omitted.

Referring to FIG. 23, the side surface of the organic layer 210 protrudes more than the outer surface of the first contact electrode CTE1 and the outer surface of the second contact electrode CTE2, so that a portion of the top surface of the organic layer 210 may be exposed without being covered by the first contact electrode CTE1 and the second contact electrode CTE2. Thus, the first connection electrode BE1 may be located on the side surface and a portion of the top surface of the organic layer 210, and the outer surface of the first contact electrode CTE1. Further, the second connection electrode BE2 may be located on the side surface and a portion of the top surface of the organic layer, and the outer surface of the second contact electrode CTE2.

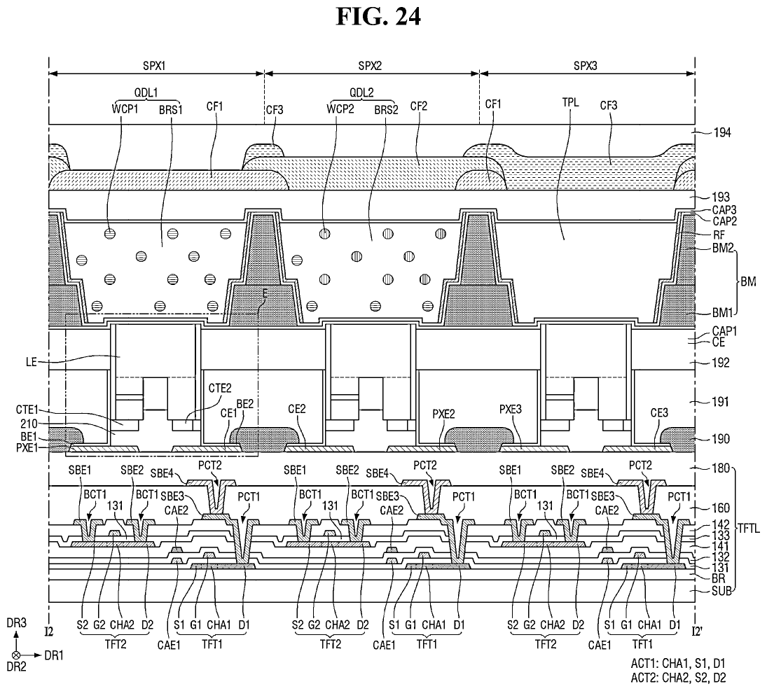

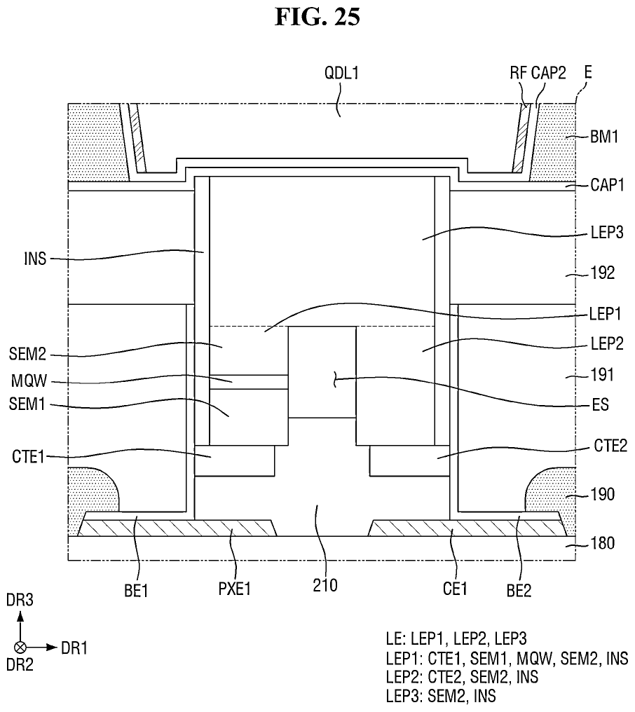

FIG. 24 is a cross-sectional view showing the display panel taken along the line I2-I2′ of FIG. 19. FIG. 25 is a cross-sectional view illustrating an example of area E of FIG. 24.

The one or more embodiments corresponding to FIGS. 24 and 25 is different from the one or more embodiments corresponding to FIGS. 21 and 22 in that the first contact electrode CTE1 is not located on the passivation layer INS located on the outer surface of the first portion LEP1 of the light-emitting element LE, and the second contact electrode CTE2 is not located on the passivation layer INS located on the outer surface of the second portion LEP2 of the light-emitting element LE. In the one or more embodiments corresponding to FIGS. 24 and 25, redundant description of the parts already described in the one or more embodiments corresponding to FIGS. 21 and 22 will be omitted.

In accordance with the one or more embodiments corresponding to FIGS. 24 and 25, the outer surface of the first contact electrode CTE1 may be aligned with the side surface of the organic layer 210. Accordingly, the outer surface of the first contact electrode CTE1, the side surface of the organic layer 210, and one surface (e.g., the outer surface) of the passivation layer INS may be connected to be flat. Therefore, it is possible to reduce or prevent the likelihood of the first connection electrode BE1 being disconnected on the outer surface of the first contact electrode CTE1, the side surface of the organic layer 210, and one surface (e.g., the outer surface) of the passivation layer INS.

Further, the outer surface of the second contact electrode CTE2 may be aligned with the side surface of the organic layer 210. Accordingly, the outer surface of the second contact electrode CTE2, the side surface of the organic layer 210, and one surface (e.g., the outer surface) of the passivation layer INS may be connected to be flat. Therefore, it is possible to reduce or prevent the likelihood of the second connection electrode BE2 being disconnected on the outer surface of the second contact electrode CTE2, the side surface of the organic layer 210, and one surface (e.g., the outer surface) of the passivation layer INS.

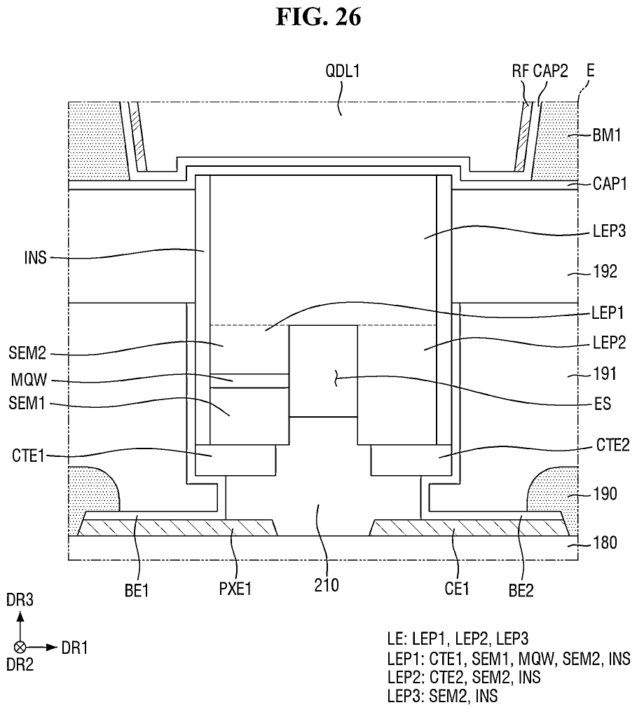

FIG. 26 is a cross-sectional view showing still another example of area E of FIG. 24.

The one or more embodiments corresponding to FIG. 26 is different from the one or more embodiments corresponding to FIG. 25 in that the outer surface of the first contact electrode CTE1 protrudes more than the side surface of the organic layer 210, and the outer surface of the second contact electrode CTE2 protrudes more than the side surface of the organic layer 210, and in the one or more embodiments corresponding to FIG. 26, redundant description of the parts already described in the one or more embodiments corresponding to FIG. 25 will be omitted.

Referring to FIG. 26, the outer surface of the first contact electrode CTE1 protrudes more than the side surface of the organic layer 210, so that a portion of the bottom surface of the first contact electrode CTE1 may be exposed. Thus, the first connection electrode BE1 may be located on the side surface of the organic layer 210, and the outer surface and a portion of the bottom surface of the first contact electrode CTE1.

Further, the outer surface of the second contact electrode CTE2 protrudes more than the side surface of the organic layer 210, so that a portion of the bottom surface of the second contact electrode CTE2 may be exposed. Thus, the second connection electrode BE2 may be located on the side surface of the organic layer 210, and the outer surface and a portion of the bottom surface of the second contact electrode CTE2.

In accordance with the one or more embodiments corresponding to FIG. 26, the first connection electrode BE1 is also in contact with a portion of the bottom surface of the first contact electrode CTE1, so that the contact area between the first contact electrode CTE1 and the first connection electrode BE1 may increase. Therefore, the contact resistance between the first contact electrode CTE1 and the first connection electrode BE1 may be reduced, and the first contact electrode CTE1 and the first connection electrode BE1 may be more stably connected.

Further, the second connection electrode BE2 is also in contact with a portion of the bottom surface of the second contact electrode CTE2, so that the contact area between the second contact electrode CTE2 and the second connection electrode BE2 may increase. Therefore, the contact resistance between the second contact electrode CTE2 and the second connection electrode BE2 may be reduced, and the second contact electrode CTE2 and the second connection electrode BE2 may be more stably connected.

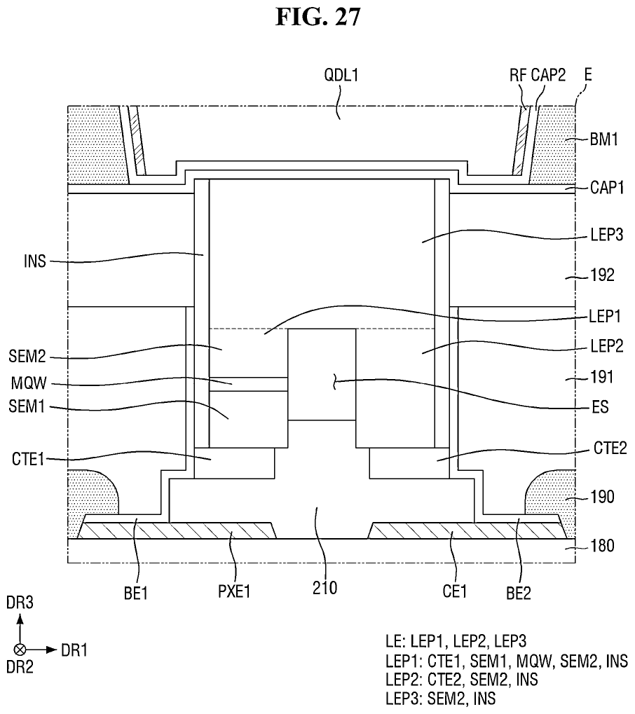

FIG. 27 is a cross-sectional view showing still another example of area E of FIG. 24.

The one or more embodiments corresponding to FIG. 27 is different from the one or more embodiments corresponding to FIG. 25 in that the side surface of the organic layer 210 protrudes more than the outer surface of the first contact electrode CTE1 and the outer surface of the second contact electrode CTE2, and in the one or more embodiments corresponding to FIG. 27, redundant description of the parts already described in the one or more embodiments corresponding to FIG. 25 will be omitted.

Referring to FIG. 27, the side surface of the organic layer 210 protrudes more than the outer surface of the first contact electrode CTE1 and the outer surface of the second contact electrode CTE2, so that a portion of the top surface of the organic layer 210 may be exposed without being covered by the first contact electrode CTE1 and the second contact electrode CTE2. Thus, the first connection electrode BE1 may be located on the side surface and a portion of the top surface of the organic layer 210, and the outer surface of the first contact electrode CTE1. Further, the second connection electrode BE2 may be located on the side surface and a portion of the top surface of the organic layer, and the outer surface of the second contact electrode CTE2.

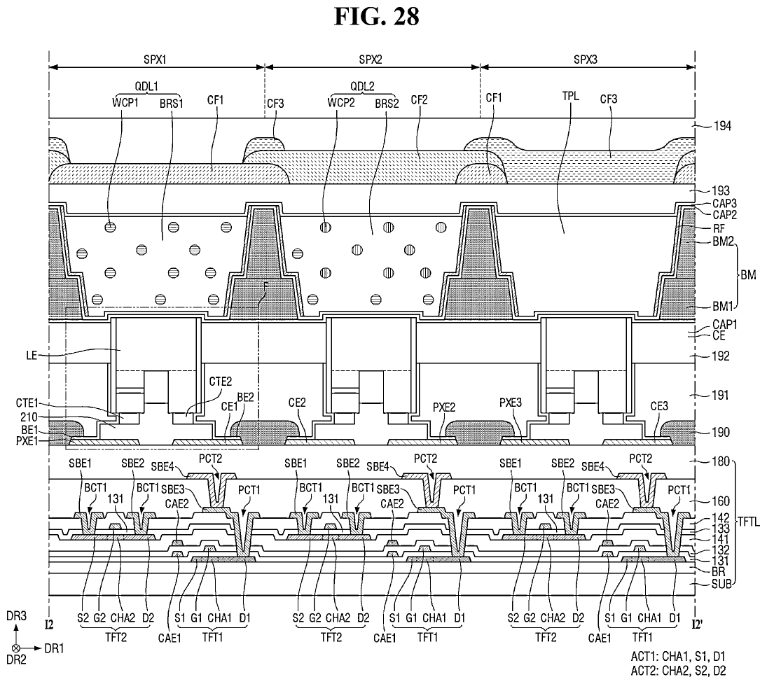

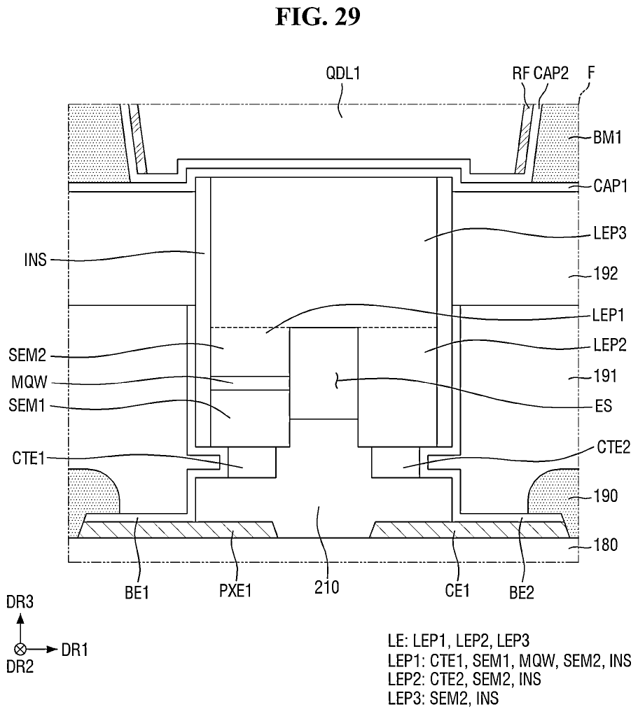

FIG. 28 is a cross-sectional view showing the display panel taken along the line I2-I2′ of FIG. 19. FIG. 29 is a cross-sectional view illustrating an example of area F of FIG. 28.

The one or more embodiments corresponding to FIGS. 28 and 29 is different from the one or more embodiments corresponding to FIGS. 20 and 21 in that the contact electrode CTE is located on a portion of the bottom surface of the first semiconductor layer SEM1. In the one or more embodiments corresponding to FIGS. 28 and 29, redundant description of the parts already described in the one or more embodiments corresponding to FIGS. 20 and 21 will be omitted.

In accordance with the one or more embodiments corresponding to FIGS. 28 and 29, the first contact electrode CTE1 is located on a portion of the bottom surface of the first portion LEP1 of the light-emitting element LE, so that the length in the first direction DR1 (or the length in the second direction DR2) of the first contact electrode CTE1 is less than the length in the first direction DR1 (or the length in the second direction DR2) of the bottom surface of the first portion LEP1. The first contact electrode CTE1 is not located on the passivation layer INS located on the outer surface of the first portion LEP1 of the light-emitting element LE.

The edge of the top surface of the organic layer 210 may be exposed without being covered by the first contact electrode CTE1. Therefore, the first connection electrode BE1 may be located on the edge of the top surface of the organic layer 210 that is exposed without being covered by the first contact electrode CTE1. Further, the first connection electrode BE1 may be located on the bottom surface of the first portion LEP1 of the light-emitting element LE.

Because the second contact electrode CTE2 is located on a portion of the bottom surface of the second portion LEP2 of the light-emitting element LE, the length in the first direction DR1 (or the length in the second direction DR2) of the second contact electrode CTE2 is less than the length in the first direction DR1 (or the length in the second direction DR2) of the bottom surface of the second portion LEP2. The second contact electrode CTE2 is not located on the passivation layer INS located on the outer surface of the second portion LEP2 of the light-emitting element LE.

The edge of the top surface of the organic layer 210 may be exposed without being covered by the second contact electrode CTE2. Therefore, the second connection electrode BE2 may be located on the edge of the top surface of the organic layer 210 that is exposed without being covered by the second contact electrode CTE2. Further, the second connection electrode BE2 may be located on the bottom surface of the second portion LEP2 of the light-emitting element LE.

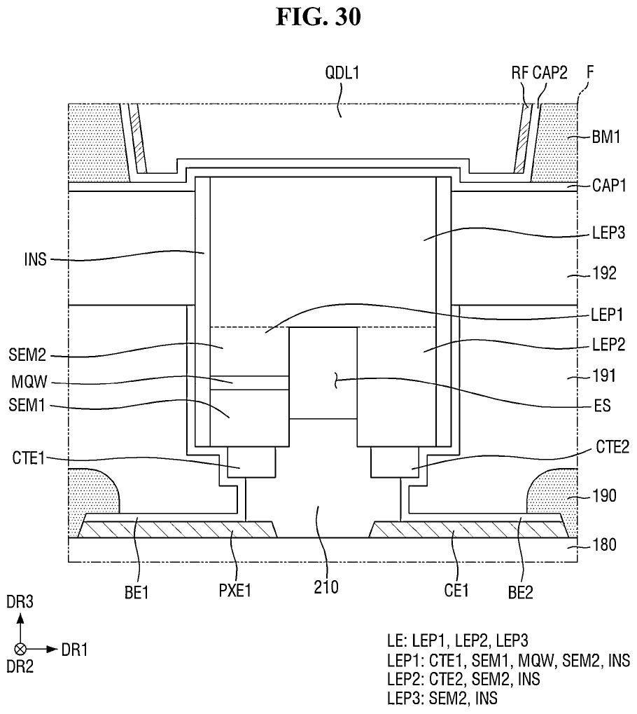

FIG. 30 is a cross-sectional view showing still another example of area F of FIG. 28.

The one or more embodiments corresponding to FIG. 30 is different from the one or more embodiments corresponding to FIG. 29 in that the outer surface of the first contact electrode CTE1 protrudes more than the side surface of the organic layer 210, and the outer surface of the second contact electrode CTE2 protrudes more than the side surface of the organic layer 210, and in the one or more embodiments corresponding to FIG. 30, redundant description of the parts already described in the one or more embodiments corresponding to FIG. 29 will be omitted.

Referring to FIG. 30, the outer surface of the first contact electrode CTE1 protrudes more than the side surface of the organic layer 210, so that a portion of the bottom surface of the first contact electrode CTE1 may be exposed. Thus, the first connection electrode BE1 may be located on the side surface of the organic layer 210, and the outer surface and a portion of the bottom surface of the first contact electrode CTE1.

Further, the outer surface of the second contact electrode CTE2 protrudes more than the side surface of the organic layer 210, so that a portion of the bottom surface of the second contact electrode CTE2 may be exposed. Thus, the second connection electrode BE2 may be located on the side surface of the organic layer 210, and the outer surface and a portion of the bottom surface of the second contact electrode CTE2.

In accordance with the one or more embodiments corresponding to FIG. 30, the first connection electrode BE1 is also in contact with a portion of the bottom surface of the first contact electrode CTE1, so that the contact area between the first contact electrode CTE1 and the first connection electrode BE1 may increase. Accordingly, the contact resistance between the first contact electrode CTE1 and the first connection electrode BE1 may be reduced, and the first contact electrode CTE1 and the first connection electrode BE1 may be more stably connected.

Further, the second connection electrode BE2 is also in contact with a portion of the bottom surface of the second contact electrode CTE2, so that the contact area between the second contact electrode CTE2 and the second connection electrode BE2 may increase. Therefore, the contact resistance between the second contact electrode CTE2 and the second connection electrode BE2 may be reduced, and the second contact electrode CTE2 and the second connection electrode BE2 may be more stably connected.

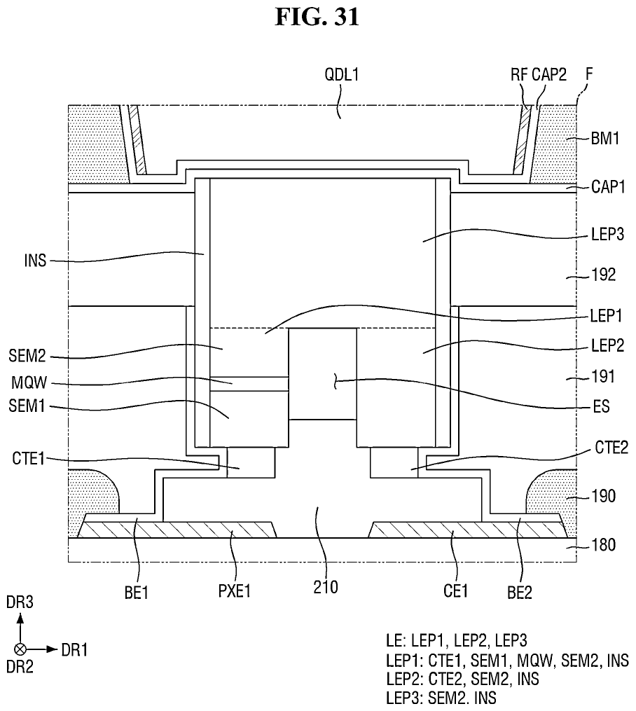

FIG. 31 is a cross-sectional view showing still another example of area F of FIG. 28.

The one or more embodiments corresponding to FIG. 31 is different from the one or more embodiments corresponding to FIG. 29 in that the side surface of the organic layer 210 protrudes more than the outer surface of the first contact electrode CTE1 and the outer surface of the second contact electrode CTE2, and in the one or more embodiments corresponding to FIG. 31, redundant description of the parts already described in the one or more embodiments corresponding to FIG. 29 will be omitted.

Referring to FIG. 31, the side surface of the organic layer 210 protrudes more than the outer surface of the first contact electrode CTE1 and the outer surface of the second contact electrode CTE2, so that a portion of the top surface of the organic layer 210 may be exposed without being covered by the first contact electrode CTE1 and the second contact electrode CTE2. Thus, the first connection electrode BE1 may be located on the side surface and a portion of the top surface of the organic layer 210, and the outer surface of the first contact electrode CTE1. Further, the second connection electrode BE2 may be located on the side surface and a portion of the top surface of the organic layer, and the outer surface of the second contact electrode CTE2.

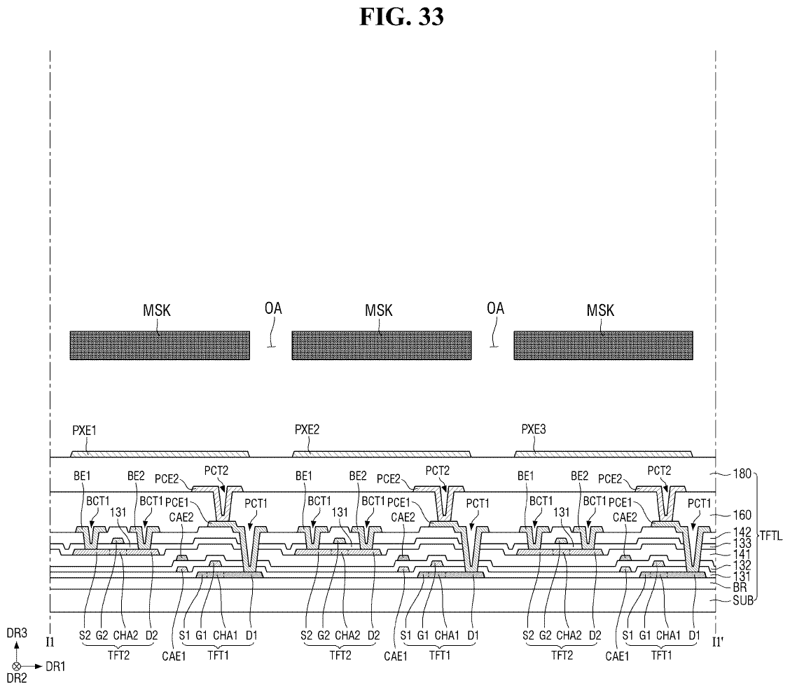

FIG. 32 is a flowchart illustrating a method for manufacturing a display device according to one or more embodiments. FIGS. 33 to 41 are cross-sectional views illustrating a method for manufacturing a display device according to one or more embodiments. FIGS. 33 to 41 show examples of a cross section of the display panel taken along the line I1-I1′ of FIG. 6.

First, as shown in FIG. 33, the thin film transistor layer TFTL is formed on the substrate SUB, and the pixel electrodes PXE1, PXE2, and PXE3 are formed on the thin film transistor layer TFTL using a mask MSK (operation S110 in FIG. 32).

The barrier layer BR is formed on the substrate SUB, and the first channel regions CHA1, the first source regions S1, and the first drain regions D1 of the first thin film transistors TFT1 are formed on the barrier layer BR using a photolithography process.

Then, the first gate-insulating layer 131 is formed on the first channel regions CHA1, the first source regions S1, and the first drain regions D1 of the first thin film transistors TFT1. The first gate electrodes G1 and the first capacitor electrodes CAE1 of the first thin film transistors TFT1 are formed on the first gate-insulating layer 131.

The first channel regions CHA1, the first source regions S1, and the first drain regions D1 of the first thin film transistors TFT1 may include polycrystalline silicon, monocrystalline silicon, low-temperature polycrystalline silicon, or amorphous silicon.

Then, the second gate-insulating layer 132 is formed on the first gate electrodes G1 and the first capacitor electrodes CAE1 of the first thin film transistors TFT1. The second capacitor electrodes CAE2 are formed on the second gate-insulating layer 132 using a photolithography process.

Then, the first interlayer insulating layer 141 is formed on the second capacitor electrodes CAE. The second channel regions CHA2, the second source regions S2, and the second drain regions D2 of the second thin film transistors TFT2 are formed on the first interlayer insulating layer 141 using a photolithography process.

The second channel regions CHA2, the second source regions S2, and the second drain regions D2 of the second thin film transistors TFT2 may include an oxide semiconductor containing indium (In), gallium (Ga), and oxygen (O).

Then, the third gate-insulating layer 133 is formed on the second channel regions CHA2, the second source regions S2, and the second drain regions D2 of the second thin film transistors TFT2. The second gate electrodes G2 of the second thin film transistors TFT2 are formed on the third gate-insulating layer 133 using a photolithography process.

Then, the second interlayer insulating layer 142 is formed on the second gate electrodes G2 of the second thin film transistors TFT2. Further, the first source contact hole PCT1 penetrating the first gate-insulating layer 131, the second gate-insulating layer 132, the first interlayer insulating layer 141, the third gate-insulating layer 133, and the second interlayer insulating layer 142, the second source connection contact hole BCT1 penetrating the second interlayer insulating layer 142, and the third source connection contact hole BCT2 penetrating the second interlayer insulating layer 142, may be formed using a photolithography process. Further, the first source connection electrode SBE3, the second source connection electrode SBE1, and the third source connection electrode SBE2 are formed on the second interlayer insulating layer 142 using a photolithography process.

Then, the first organic layer 160 is formed on the first source connection electrode SBE3, the second source connection electrode SBE1, and the third source connection electrode SBE2. The fourth source connection electrode SBE4 is formed on the first organic layer 160 using a photolithography process.

Then, the second organic layer 180 is formed on the fourth source connection electrode SBE4, and the pixel electrodes PXE1, PXE2, and PXE3 are formed on the second organic layer 180 using a photolithography process. For example, after a pixel electrode layer covering the entire second organic layer 180 and a photoresist covering the entire pixel electrode layer are formed, the pixel electrode layer is exposed by removing the photoresist overlapping an opening OA of the mask MSK, and then, the pixel electrodes PXE1, PXE2, and PXE3 are formed by etching the exposed pixel electrode layer. The photoresist may be removed by an ashing process.

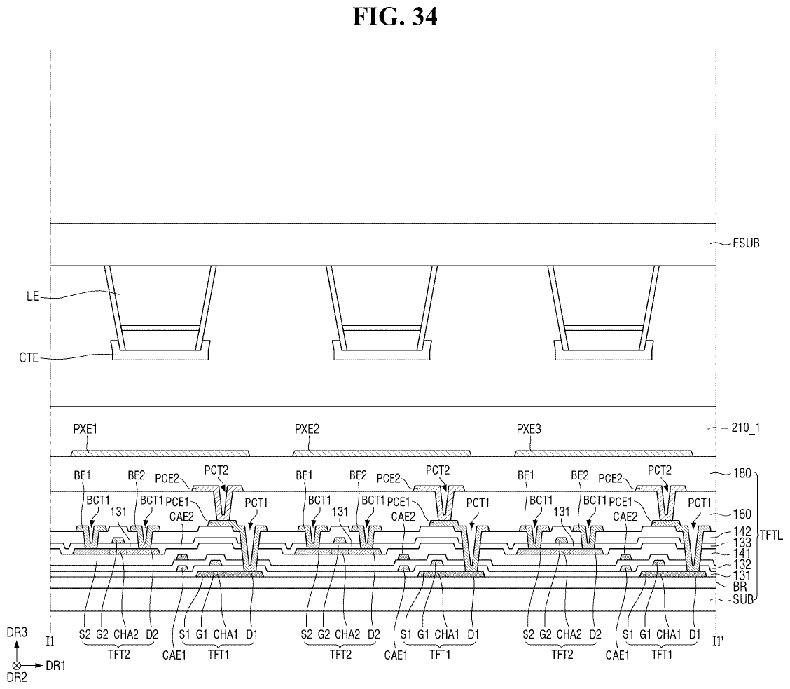

Second, as shown in FIG. 34, an adhesive layer 210_1 (or a temporary adhesive layer or a temporary fixing layer) is formed on the pixel electrodes PXE1, PXE2, and PXE3 (operation S120 in FIG. 32).

The adhesive layer 210_1 serves to temporarily fix or adhere the plurality of light-emitting elements LE to reduce or prevent the likelihood of them tilting or falling during the process of transferring the plurality of light-emitting elements LE to the display panel 100. To this end, the thickness of the adhesive layer 210_1 may be about 2 μm or less, but the present disclosure is not limited thereto.

The adhesive layer 210_1 may be a photosensitive organic layer, such as a photoresist. Alternatively, the adhesive layer 210_1 may be formed of acryl resin, epoxy resin, phenolic resin, polyamide resin, polyimide resin, or the like.

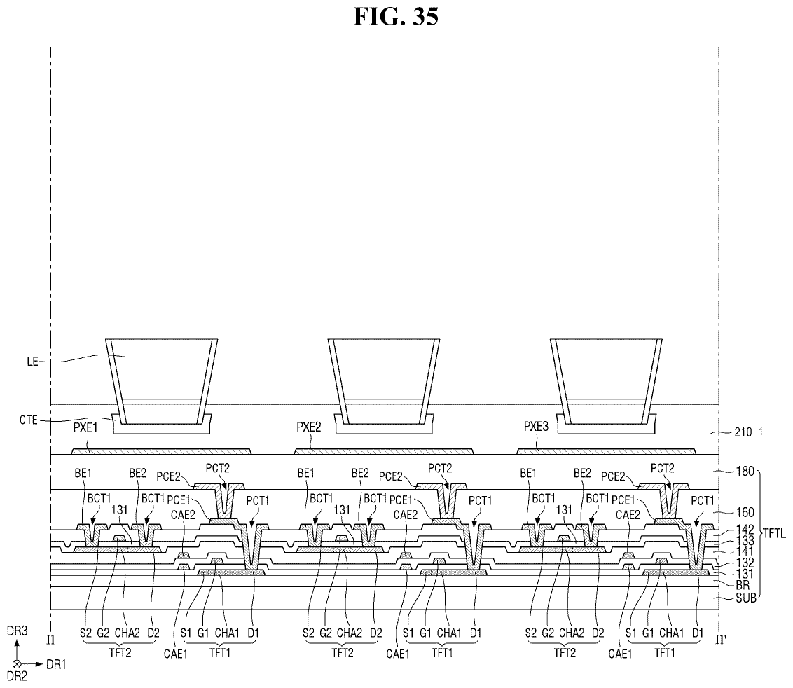

Third, as shown in FIG. 35, the plurality of light-emitting elements LE are fixed to the adhesive layer 210_1, and a light-emitting element substrate ESUB is detached (operation S130 in FIG. 32).

A portion of each of the plurality of light-emitting elements LE may be temporarily fixed while being embedded in the adhesive layer 210_1. For example, the contact electrode CTE and the first semiconductor layer SEM1 of each of the plurality of light-emitting elements LE may be fixed while being embedded in the adhesive layer 210_1.

When the adhesive layer 210_1 is a photosensitive organic layer, such as a photoresist, the adhesive layer 210_1 is cured at a first temperature, and then, a portion of each of the plurality of light-emitting elements LE is fixed to the adhesive layer 210_1. Then, the adhesive layer 210_1 may be completely cured at a second temperature higher than the first temperature. The first temperature may be approximately 150 degrees, and the second temperature may be approximately 250 degrees, but the present disclosure is not limited thereto.

The plurality of light-emitting elements LE may be separated from the light-emitting element substrate ESUB using a laser lift process.

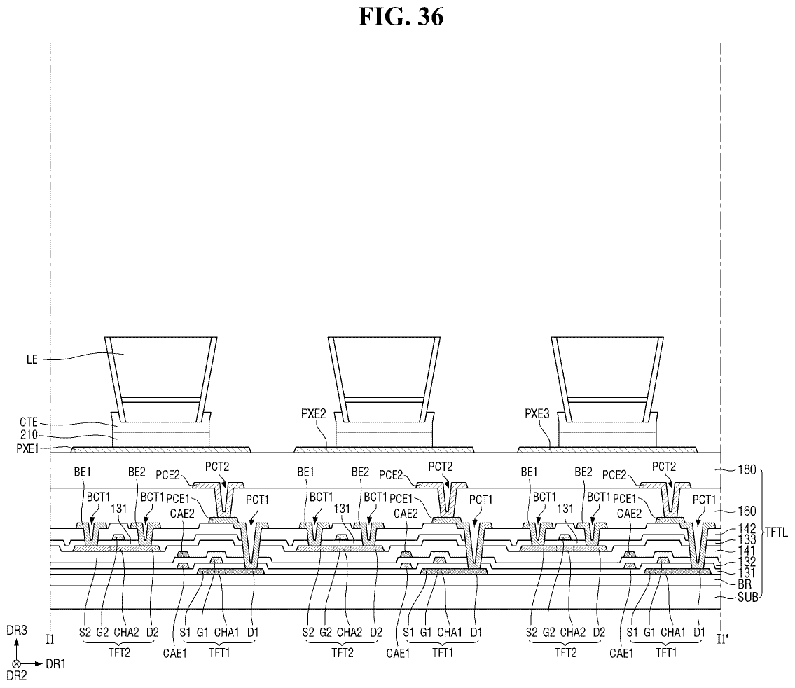

Fourth, as shown in FIG. 36, a portion of the adhesive layer 2101 is removed to form the organic layer 210 (operation S140 in FIG. 32).

A portion of the adhesive layer 210_1 is removed while using the light-emitting element LE as a mask to form the organic layer 210. That is, the organic layer 210 may be the residue of the adhesive layer 210_1.

Because the adhesive layer 210_1 located on the pixel electrodes PXE1, PXE2, and PXE3 is removed, the top surface edge and the side surfaces of each of the pixel electrodes PXE1, PXE2, and PXE3 may be exposed. When the adhesive layer 2101 is a photosensitive organic layer, such as a photoresist, it may be removed by an ashing process.

Then, as in operations S150 to S170, the connection electrodes BE are formed to connect the pixel electrodes PXE1, PXE2, and PXE3 and the contact electrodes CTE of the plurality of light-emitting elements LE.

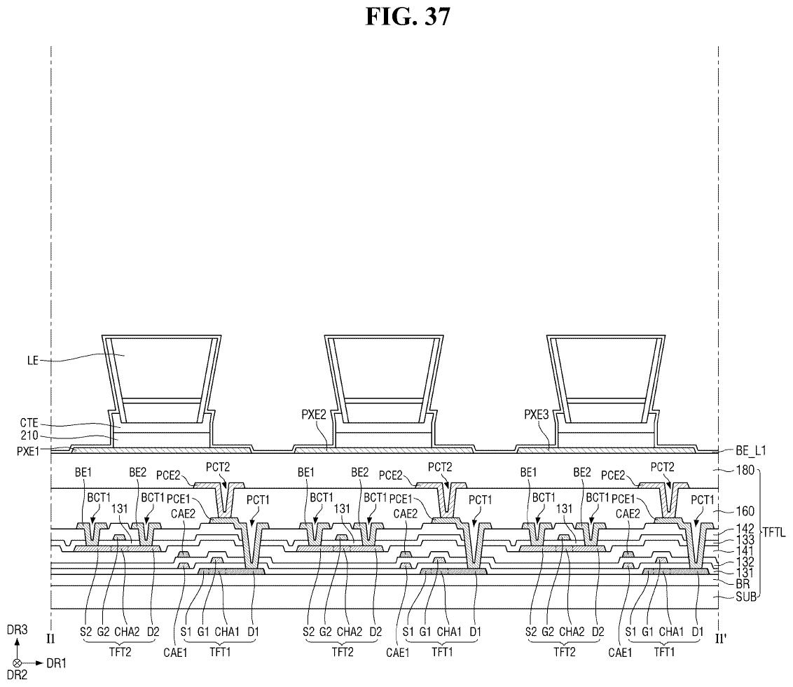

Fifth, as shown in FIG. 37, a first connection electrode layer BE_L1 is formed to cover the pixel electrodes PXE1, PXE2, and PXE3, the organic layer 210, and the plurality of light-emitting elements LE (operation S150 in FIG. 32).

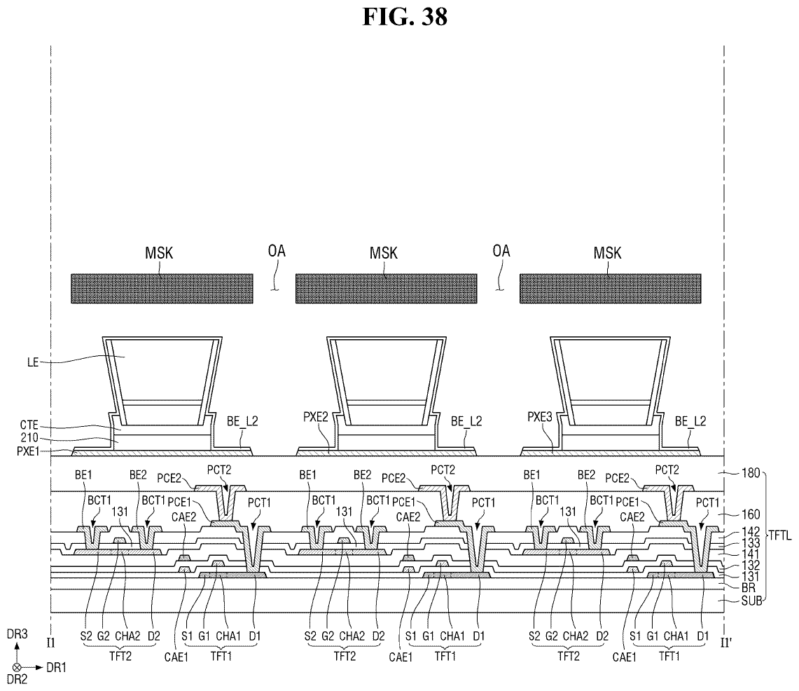

Sixth, as shown in FIG. 38, a second connection electrode layer BE_L2 is formed using the mask MSK (operation S160 in FIG. 32).

The mask MSK may be substantially the same mask as the mask used in operation S110 to form the pixel electrodes PXE1, PXE2, and PXE3. After a photoresist covering the entire first connection electrode layer BE_L1 is formed, the first connection electrode layer BE_L1 is exposed by removing the photoresist overlapping the opening OA of the mask MSK, and then, the second connection electrode layer BE_L2 is formed by etching the exposed first connection electrode layer BE_L1. The photoresist may be removed by an ashing process.

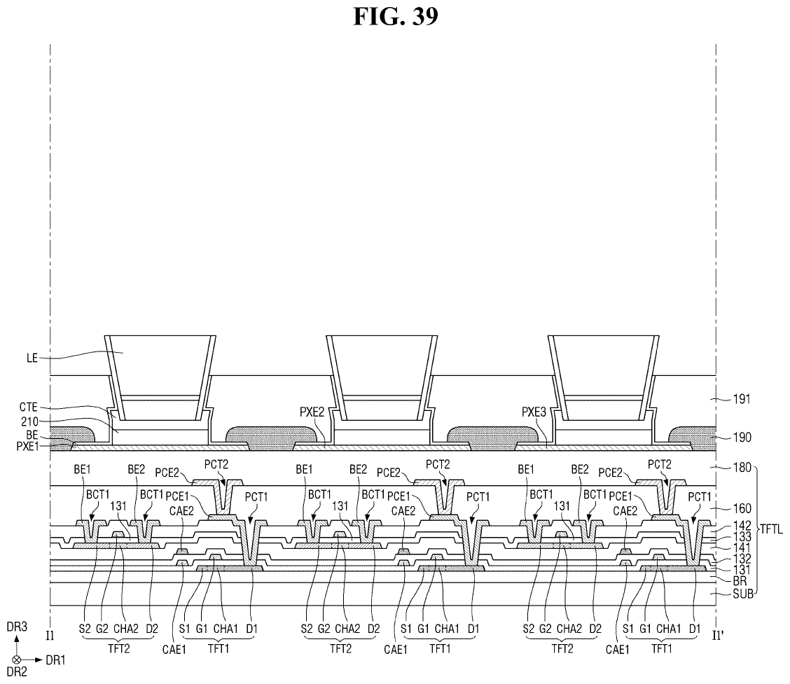

Seventh, as shown in FIG. 39, the bank 190 and the third organic layer 191 are sequentially formed, and the connection electrodes BE are formed by etching the second connection electrode layer BE_L2 that is exposed without being covered by the third organic layer 191 (operation S170 in FIG. 32).

The bank 190 may be formed to cover the edge of each of the pixel electrodes PXE1, PXE2, and PXE3. The third organic layer 191 may cover the bank 190 and a portion of the side surface of each of the plurality of light-emitting elements LE.

The second connection electrode layer BE_L2 that is exposed without being covered by the third organic layer 191 may be etched. Therefore, the third organic layer 191 covers the connection electrode BE, but at least a portion of the connection electrode BE may be exposed without being covered by the third organic layer 191.

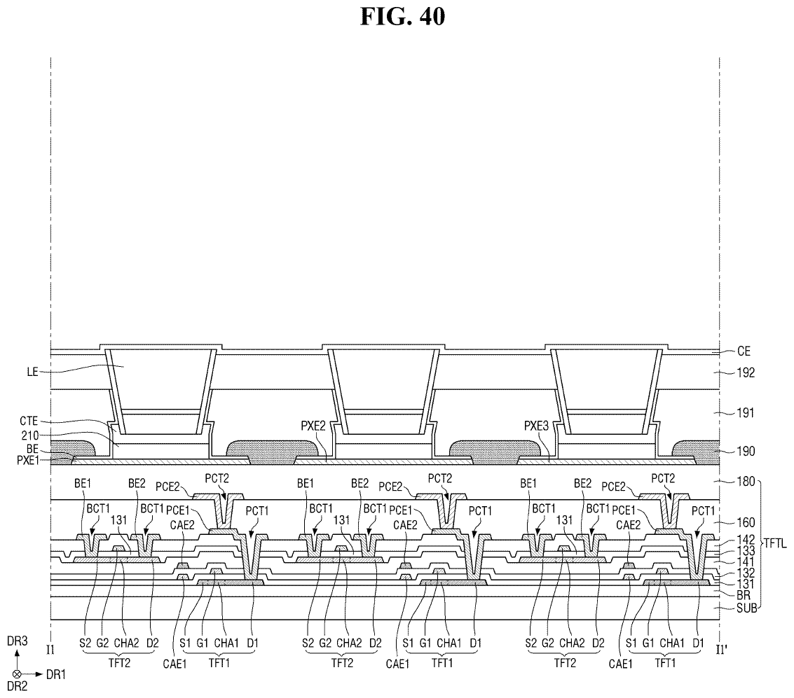

Eighth, as shown in FIG. 40, the fourth organic layer 192 is formed, and the common electrode CE is formed on the fourth organic layer 192 and the top surface of each of the plurality of light-emitting elements LE (operation S180 in FIG. 32).

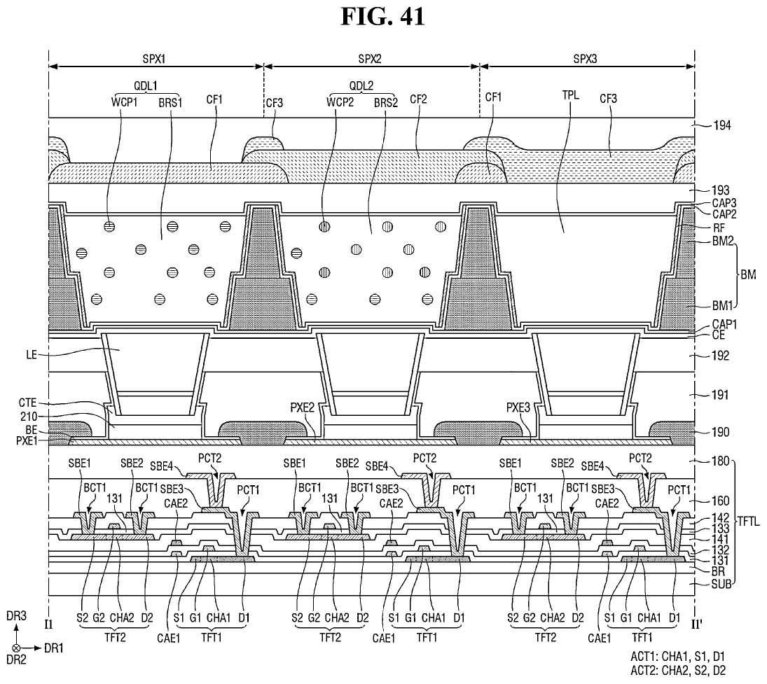

Ninth, as shown in FIG. 41, the light-blocking layer BM, the first and second light conversion layers QDL1 and QDL2, and the color filters CF1, CF2, and CF3 are formed (operation S190 in FIG. 32).

The first capping layer CAP1 is formed on the common electrode CE, the first light-blocking layer BM1 is formed on the first capping layer CAP1, and the second light-blocking layer BM2 is formed on the first light-blocking layer BM1. The first light-blocking layer BM1 and the second light-blocking layer BM2 may overlap the bank 190 in the third direction DR3, and may not overlap the plurality of light-emitting elements LE. The length of the first light-blocking layer BM1 in the first direction DR1 or the length of the first light-blocking layer BM1 in the second direction DR2 may be longer than the length of the second light-blocking layer BM2 in the first direction DR1 or the length of the second light-blocking layer BM2 in the second direction DR2.

Then, the second capping layer CAP2 is formed on the first capping layer CAP1 and the light-blocking layer BM, and the reflection layer RF is formed on the side surface of the first light-blocking layer BM1 and the side surface of the second light-blocking layer BM2.

Then, in the regions partitioned from the first light-blocking layer BM1 and the second light-blocking layer BM2, the first light conversion layer QDL1 is formed in the region corresponding to the first sub-pixel SPX1, the second light conversion layer QDL2 is formed in the region corresponding to the second sub-pixel SPX2, and the light-transmitting layer TPL is formed in the region corresponding to the third sub-pixel SPX3.

Then, the third capping layer CAP3 is formed on the second capping layer CAP2, the first light conversion layer QDL1, the second light conversion layer QDL2, and the light-transmitting layer TPL, and the fifth organic layer 193 is formed on the third capping layer CAP3.

Then, the plurality of color filters CF1, CF2, and CF3 are formed on the fifth organic layer 193, and the sixth organic layer 194 is formed on the plurality of color filters CF1, CF2, and CF3.

Although FIGS. 32 to 41 mainly illustrate that each of the plurality of light-emitting elements LE is a vertical type micro LED, each of the light-emitting elements LE may be a flip type micro LED as shown in FIGS. 20 to 31.

As shown in FIGS. 32 to 41, the adhesive layer 210_1 (or the temporary adhesive layer or the temporary fixing layer) is formed on the pixel electrodes PXE1, PXE2, and PXE3, and the adhesive layer 210_1 is completely cured after a portion of each of the plurality of light-emitting elements LE is embedded in the adhesive layer 210_1, thereby fixing the plurality of light-emitting elements LE to the adhesive layer 210_1. Therefore, in the process of transferring the plurality of light-emitting elements LE to the display panel 100, it is possible to reduce or prevent the likelihood of the plurality of light-emitting elements LE tilting or falling. Accordingly, it is possible to reduce or reduce or prevent the likelihood of each of the plurality of light-emitting elements LE becoming unable to be electrically connected to the pixel electrode.

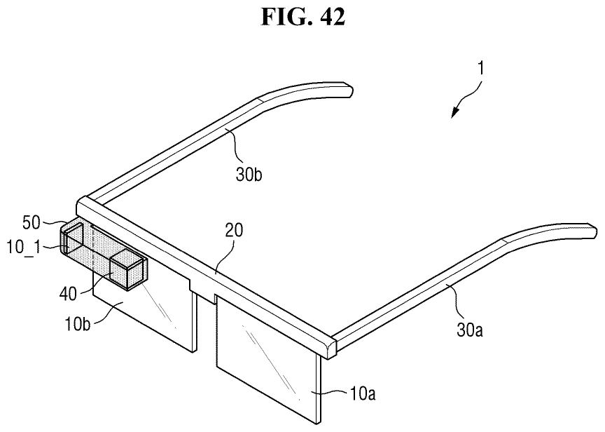

FIG. 42 is a diagram illustrating a virtual reality device including a display device according to one or more embodiments. FIG. 42 illustrates a virtual reality device 1 to which the display device 10 according to one or more embodiments is applied.

Referring to FIG. 42, the virtual reality device 1 according to one or more embodiments may be a glass-type device. The virtual reality device 1 according to one or more embodiments may include the display device 10, a left lens 10a, a right lens 10b, a support frame 20, temples 30a and 30b, a reflection member 40, and a display device storage 50.

Although FIG. 42 illustrates the virtual reality device 1 including the temples 30a and 30b, the virtual reality device 1 according to one or more embodiments may be applied to a head mounted display including a head mounted band that may be worn on a head, instead of the temples 30a and 30b. That is, the virtual reality device 1 according to one or more embodiments is not limited to that shown in FIG. 42, and may be applied in various forms to various electronic devices.

The display device storage 50 may include the display device 10 and the reflection member 40. The image displayed on the display device 10 may be reflected by the reflection member 40 and provided to a user's right eye through the right lens 10b. Accordingly, the user can view the virtual reality image displayed on the display device 10 through the right eye.

FIG. 42 illustrates that the display device storage 50 is located at the end of the right side of the support frame 20, but the present disclosure is not limited thereto. For example, the display device storage 50 may be located at the left end of the support frame 20, and in this case, the image displayed on the display device 10 may be reflected by the reflection member 40 and provided to a user's left eye through the left lens 10a. Accordingly, the user can view the virtual reality image displayed on the display device 10 through the left eye. Alternatively, the display device storage 50 may be located at both the left end and the right end of the support frame 20. In that case, the user can view the virtual reality image displayed on the display device 10 through both the left eye and the right eye.

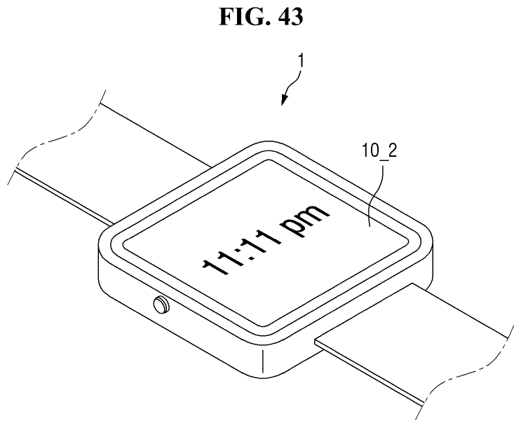

FIG. 43 is a diagram illustrating a smart watch including a display device according to one or more embodiments.

Referring to FIG. 43, the display device 10 according to one or more embodiments may be applied to the smart watch 2 that is one of the smart devices.

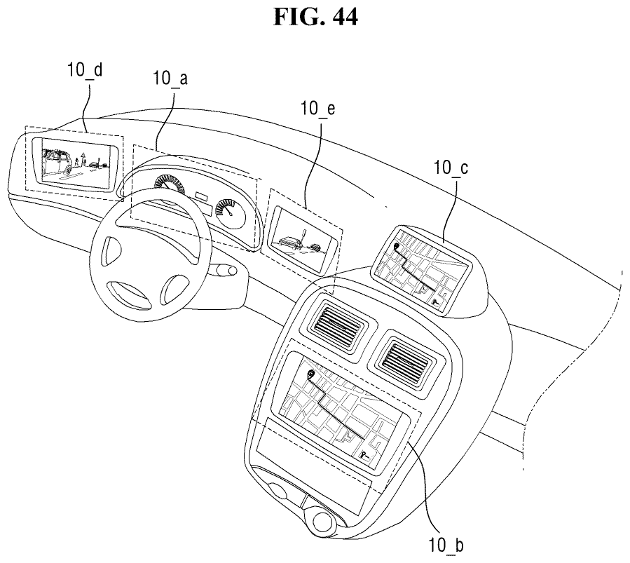

FIG. 44 is a diagram illustrating a dashboard of an automobile and a center fascia including display devices according to one or more embodiments. FIG. 43 shows an automobile to which the display device 10 according to one or more embodiments is applied.

Referring to FIG. 43, the display devices 10_a, 10_b, and 10_c according to one or more embodiments may be applied to the dashboard of the automobile, the center fascia of the automobile, or the center information display (CID) of the dashboard of the automobile. Further, the display devices 10_d, and 10_e according to one or more embodiments may be applied to a room mirror display instead of side mirrors of the automobile.

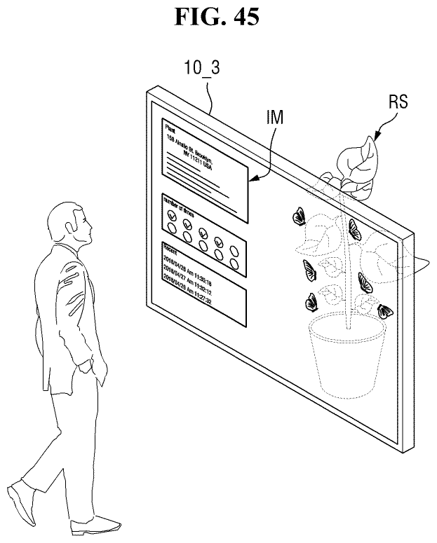

FIG. 45 is a diagram illustrating a transparent display device including a display device according to one or more embodiments.

Referring to FIG. 45, the display device 10 according to one or more embodiments may be applied to the transparent display device. The transparent display device may display an image IM, and also may transmit light. Thus, a user located on the front side of the transparent display device can view an object RS or a background on the rear side of the transparent display device as well as the image IM displayed on the display device 10. When the display device 10 is applied to the transparent display device, the substrate SUB of the display device 10 may include a light-transmitting portion capable of transmitting light or may be made of a material capable of transmitting light.

It should be understood, however, that the aspects of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a pixel electrode above the substrate;
an organic layer above the pixel electrode;
a light-emitting element above the organic layer, and comprising a contact electrode in contact with the organic layer; and
a connection electrode connected to the pixel electrode and to the contact electrode, on a side surface of the organic layer, and on a side surface of the contact electrode.

2. The display device of claim 1, wherein the light-emitting element comprises:
a first semiconductor layer above the contact electrode;
an active layer above the first semiconductor layer;
a second semiconductor layer above the active layer; and
a passivation layer on a side surface of the first semiconductor layer, on a side surface of the active layer, and on a side surface of the second semiconductor layer,
wherein the connection electrode is on the passivation layer.

3. The display device of claim 2, further comprising a first organic layer covering the connection electrode,
wherein a portion of the passivation layer is exposed without being covered by the first organic layer.

4. The display device of claim 3, further comprising:
a second organic layer above the first organic layer, and covering the portion of the passivation layer; and
a common electrode above top surfaces of the second organic layer and the second semiconductor layer.

5. The display device of claim 4, further comprising:
a bank covering an edge of the pixel electrode and an edge of the connection electrode;
a first light-blocking layer above the common electrode, and overlapping the bank in a thickness direction of the substrate;
a second light-blocking layer above the first light-blocking layer;
a light conversion layer or light-transmitting layer above the common electrode, overlapping the light-emitting element in the thickness direction of the substrate, and in a region defined by the first light-blocking layer and the second light-blocking layer; and
a color filter above the light conversion layer or the light-transmitting layer.

6. The display device of claim 2, wherein the contact electrode covers at least a portion of the passivation layer.

7. The display device of claim 2, wherein the contact electrode is on a bottom surface of the first semiconductor layer of the light-emitting element, and on a bottom surface of the passivation layer.

8. The display device of claim 2, wherein a length of the contact electrode in a first direction is less than a length of a bottom surface of the first semiconductor layer in the first direction.

9. The display device of claim 2, wherein the connection electrode is on a bottom surface of the first semiconductor layer.

10. The display device of claim 2, wherein the connection electrode is on a bottom surface of the passivation layer.

11. The display device of claim 1, wherein a side surface of the contact electrode protrudes more than a side surface of the organic layer.

12. The display device of claim 11, wherein the connection electrode is on a portion of a bottom surface of the contact electrode.

13. The display device of claim 1, wherein a side surface of the organic layer protrudes more than a side surface of the contact electrode.

14. The display device of claim 13, wherein the connection electrode is above a top surface of the organic layer exposed without being covered by the contact electrode.

15. The display device of claim 1, wherein a thickness of the organic layer is greater than a thickness of the pixel electrode.

16. The display device of claim 1, wherein a thickness of the organic layer is greater than a thickness of the contact electrode.

17. The display device of claim 1, wherein a portion of a top surface of the pixel electrode is exposed without being covered by the organic layer, and
wherein the connection electrode is above a portion of the top surface of the pixel electrode.

18. A display device comprising:
a substrate;
a pixel electrode and a common electrode above the substrate, and spaced apart from each other;
an organic layer above the pixel electrode and the common electrode;
a light-emitting element above the organic layer, and comprising a first contact electrode and a second contact electrode in contact with the organic layer;
a first connection electrode connected to the pixel electrode and the first contact electrode, on a portion of a side surface of the organic layer, and on a side surface of the first contact electrode; and
a second connection electrode connected to the common electrode and the second contact electrode, on another portion of the side surface of the organic layer, and on a side surface of the second contact electrode.

19. The display device of claim 18, wherein a portion of a top surface of the pixel electrode is exposed without being covered by the organic layer, and
wherein the first connection electrode is above the portion of the top surface of the pixel electrode.

20. The display device of claim 18, wherein the light-emitting element comprises:
a first portion above the first contact electrode, and comprising a first semiconductor layer, an active layer, and a second semiconductor layer;
a second portion above the second contact electrode, comprising the second semiconductor layer, and spaced apart from the first portion; and
a third portion connected to the first portion and the second portion, and comprising the second semiconductor layer.

21. The display device of claim 20, wherein the organic layer is between the first portion and the second portion.

22. The display device of claim 20, wherein the light-emitting element further comprises a passivation layer on an outer surface of the first portion, on an outer surface of the second portion, and on a side surface of the third portion.

23. The display device of claim 20, wherein the first connection electrode is on an outer surface of the first portion, and on a part of a side surface of the third portion, and
wherein the second connection electrode is on an outer surface of the second portion and another part of the side surface of the third portion.

24. A method for manufacturing a display device, the method comprising:
forming pixel electrodes on a substrate;
forming an adhesive layer covering the pixel electrodes;
fixing light-emitting elements to the adhesive layer;
forming an organic layer by removing a part of the adhesive layer to expose edges of top surfaces of the pixel electrodes;
forming connection electrodes respectively connecting the pixel electrodes to contact electrodes of the light-emitting elements; and
forming a common electrode on a top surface of each of the light-emitting elements.

25. The method of claim 24, wherein the forming of the pixel electrodes on the substrate, and the forming of the adhesive layer covering the pixel electrodes, comprise using a mask.

26. The method of claim 25, wherein the forming of the connection electrodes respectively connecting the pixel electrodes to the contact electrodes of the light-emitting elements comprises:
forming a first connection electrode layer covering the pixel electrodes, the organic layer, and the light-emitting elements;
forming a second connection electrode layer by removing a part of the first connection electrode layer using the mask;
forming a bank covering edges of the pixel electrodes;
forming a third organic layer covering the bank; and
forming the connection electrodes by etching a second connection electrode layer exposed without being covered by the third organic layer.
